(19) United States
(12) Patent Application Publication
(10) Pub. No.: US 2012/0007164 A1
(43) Pub. Date: Jan. 12, 2012

(54) SEMICONDUCTOR MEMORY DEVICE AND METHOD FOR MANUFACTURING THE SAME

(75) Inventor: Takashi Sugihara, Mie-ken (JP)

(73) Assignee: Kabushiki Kaisha Toshiba, Tokyo (JP)

(21) Appl. No.: 13/176,895

(22) Filed: Jul. 6, 2011

(30) Foreign Application Priority Data
Jul. 7, 2010 (JP) 2010-154591

(51) Int. Cl. H01L 29/788; H01L 21/28

(52) U.S. Cl. 257/316; 438/593; 257/E21.209; 257/E29.3

(57) ABSTRACT

According to one embodiment, a method is disclosed for manufacturing a semiconductor memory device. The method can include forming a plurality of protruding portions in band configurations on a major surface of a semiconductor layer to extend along a first direction parallel to the major surface. The method can include forming an inter-layer insulating film to cover the protruding portions and an inner surface of a trench between the protruding portions. The method can include forming a buried conductive portion by filling a first conductive material into a space inside the trench. The method can include exposing a buried conductive portion side surface by dividing the buried conductive portion along the first direction. The method can include filling a second conductive material into a void of the buried conductive portion exposed at the side surface. In addition, the method can include removing one portion of the second conductive material.

### CROSS-REFERENCE TO RELATED APPLICATIONS

This application is based upon and claims the benefit of priority from the prior Japanese Patent Application No. 2010-154591, filed on Jul. 7, 2010; the entire contents of which are incorporated herein by reference.

### FIELD

Embodiments described herein relate generally to a semiconductor memory device and a method for manufacturing the same.

### BACKGROUND

Memory elements are downscaled to realize larger capacities and lower costs of semiconductor memory devices. In, for example, memory elements of NAND flash memory, downscaling has progressed and floating gate configurations have higher aspect ratios.

In NAND flash memory, for example, a portion of the control gate is buried between the floating gates to ensure good programming characteristics. In the case where the aspect ratio of the floating gate increases and the spacing between the floating gates becomes narrow, a void occurs easily in the buried portion when depositing a conductive material used to form the control gate in the buried portion. In the case where the void occurs in the control gate, the control gate depletes in the portion where the void occurred, which causes operation errors such as programming defects, etc.

Although the occurrence of the void recited above can be suppressed by tilting the wall surface of the floating gate, the amount of charge stored in the floating gate decreases in such a configuration because the volume of the floating gate decreases.

### BRIEF DESCRIPTION OF THE DRAWINGS

FIG. 1 is a flowchart illustrating a method for manufacturing a semiconductor memory device according to a first embodiment;

FIG. 2 is a schematic plan view illustrating the configuration of the semiconductor memory device manufactured using the method for manufacturing the semiconductor memory device according to the first embodiment;

FIG. 3A and FIG. 3B are schematic cross-sectional views illustrating the configuration of the semiconductor memory device manufactured using the method for manufacturing the semiconductor memory device according to the first embodiment;

FIG. 4A to FIG. 11B are schematic cross-sectional views in order of the processes, illustrating the method for manufacturing the semiconductor memory device according to the first embodiment;

FIG. 12 to FIG. 14 are schematic perspective views in order of the processes, illustrating the method for manufacturing the semiconductor memory device according to the first embodiment;

FIG. 15A and FIG. 15B are schematic cross-sectional views illustrating the configuration of a semiconductor memory device manufactured using a method for manufacturing a semiconductor memory device of a reference example;

FIG. 16A and FIG. 16B are schematic cross-sectional views illustrating the configuration of another semiconductor memory device manufactured using the method for manufacturing the semiconductor memory device according to the first embodiment;

FIG. 17 is a schematic cross-sectional view illustrating the configuration of another semiconductor memory device manufactured using the method for manufacturing the semiconductor memory device according to the first embodiment;

FIG. 18 is a flowchart illustrating a method for manufacturing a semiconductor memory device according to a second embodiment;

FIG. 19A to FIG. 22B are schematic cross-sectional views in order of the processes, illustrating the method for manufacturing the semiconductor memory device according to the second embodiment;

FIG. 23 to FIG. 25 are schematic perspective views in order of the processes, illustrating the method for manufacturing the semiconductor memory device according to the second embodiment; and

FIG. 26A and FIG. 26B are schematic cross-sectional views illustrating the configuration of a semiconductor memory device according to a third embodiment.

### DETAILED DESCRIPTION

In general, according to one embodiment, a method is disclosed for manufacturing a semiconductor memory device. The method can include forming a plurality of protruding portions in band configurations on a major surface of a semiconductor layer to extend along a first direction parallel to the major surface. The plurality of protruding portions are used to form electrodes. The method can include forming an inter-layer insulating film to cover the plurality of protruding portions and an inner surface of a trench between the plurality of protruding portions. The method can include forming a buried conductive portion by filling a first conductive material into a space inside the trench with the inter-layer insulating film provided around the space. The method can include exposing a buried conductive portion side surface of the buried conductive portion along a second direction parallel to the major surface and non-parallel to the first direction by dividing the buried conductive portion along the first direction. The method can include filling a second conductive material into a void of the buried conductive portion exposed at the buried conductive portion side surface. In addition, the method can include removing one portion of the second conductive material.

In general, according to another embodiment, a method is disclosed for manufacturing a semiconductor memory device. The method can include forming a plurality of protruding portions in band configurations on a major surface of a semiconductor layer to extend along a first direction parallel to the major surface. The plurality of protruding portions are used to form electrodes. The method can include forming an inter-layer insulating film to cover the plurality of protruding portions and an inner surface of a trench between the plurality of protruding portions. The method can include forming a buried conductive portion by filling a first conductive material into a space inside the trench with the inter-layer insulating film provided around the space. The method can include exposing a buried conductive portion side surface of the buried conductive portion along a second direction parallel to the major surface and non-parallel to the first direction by dividing the buried conductive portion along the first direction. The method can include filling a second conductive material into a void of the buried conductive portion exposed at the buried conductive portion side surface. In addition, the method can include dividing the inter-layer insulating film and the plurality of protruding portions along the first direction.

In general, according to another embodiment, a semiconductor memory device includes a first transistor unit, a second transistor unit, an inter-layer insulating film and a control gate electrode. The first transistor unit includes a first source region provided in a major surface of a semiconductor layer, a first drain region provided in the major surface to face the first source region in a first direction, a first channel region provided in the major surface between the first source region and the first drain region, a first tunneling insulating film provided on the first channel region, and a first electrode provided on the first tunneling insulating film. The second transistor unit is arranged with the first transistor unit in a second direction non-parallel to the first direction. The second transistor unit includes a second source region provided in the major surface, a second drain region provided in the major surface to face the second source region in the first direction, a second channel region provided in the major surface between the second source region and the second drain region, a second tunneling insulating film provided on the second channel region, and a second electrode provided on the second tunneling insulating film. The inter-layer insulating film includes a first side wall portion contacting a side wall of the first electrode on a side of the second electrode, a first apical portion contacting an upper surface of the first electrode, a second side wall portion contacting a side wall of the second electrode on a side of the first electrode, and a second apical portion contacting an upper surface of the second electrode. The control gate electrode includes a buried conductive portion buried between the first side wall portion and the second side wall portion. The buried conductive portion includes a core conductive portion having a conductive material filled into a void. The side surface of the first electrode along the second direction is recessed from a side surface of the inter-layer insulating film along the second direction.

Various embodiments will be described hereinafter with reference to the accompanying drawings.

The drawings are schematic or conceptual; and the relationships between the thickness and the width of portions, the proportions of sizes among portions, etc., are not necessarily the same as the actual values thereof. Further, the dimensions and the proportions may be illustrated differently among the drawings, even for identical portions.

In the specification and the drawings of the application, components similar to those described in regard to a drawing thereinabove are marked with like reference numerals, and a detailed description is omitted as appropriate.

### First Embodiment

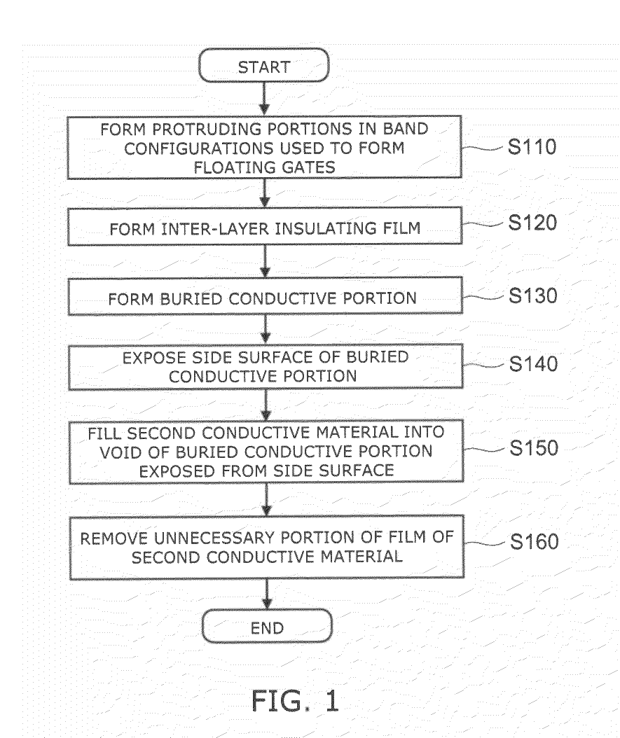

FIG. 1 is a flowchart illustrating a method for manufacturing a semiconductor memory device according to a first embodiment.

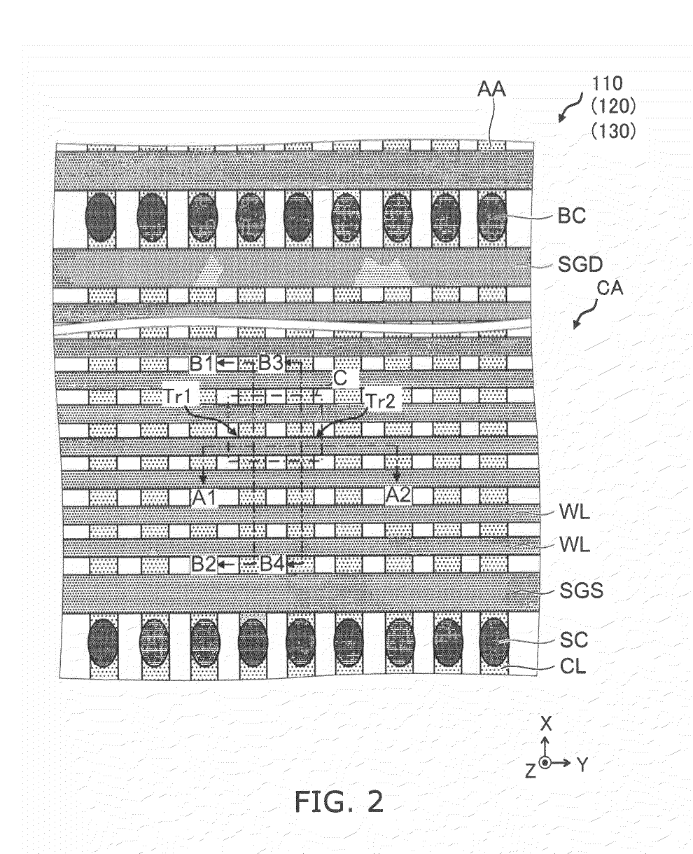

FIG. 2 is a schematic plan view illustrating the configuration of the semiconductor memory device manufactured using the method for manufacturing the semiconductor memory device according to the first embodiment.

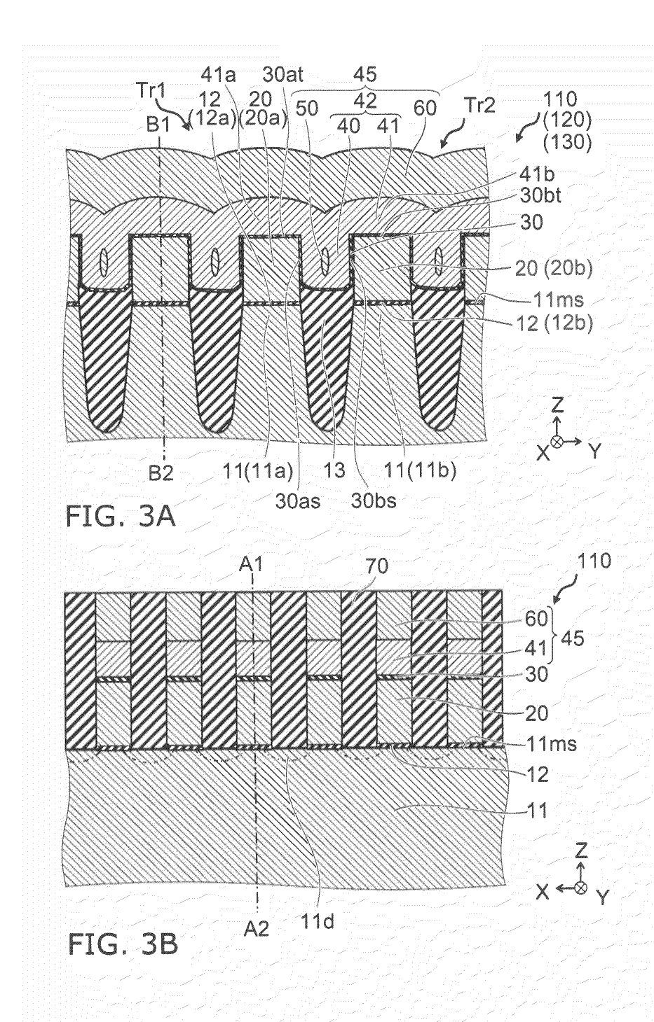

FIG. 3A and FIG. 3B are schematic cross-sectional views illustrating the configuration of the semiconductor memory device manufactured using the method for manufacturing the semiconductor memory device according to the first embodiment.

Namely, FIG. 3A is a cross-sectional view along line A1-A2 of FIG. 2; and FIG. 3B is a cross-sectional view along line B1-B2 of FIG. 2.

Hereinbelow, the case is described where the semiconductor memory device manufactured using the method for manufacturing the semiconductor memory device according to the embodiment is a NAND flash memory.

First, an overview of the configuration of the semiconductor memory device manufactured using the method for manufacturing the semiconductor memory device according to the embodiment will be described using FIG. 2, FIG. 3A, and FIG. 3B.

As illustrated in FIG. 2, a cell array region CA is provided in the semiconductor memory device 110 according to the embodiment. The plane in which the cell array region is provided is taken as an X-Y plane; and a direction perpendicular to the X-Y plane is taken as a Z-axis direction.

In other words, the direction perpendicular to the major surface of the semiconductor layer in which the cell array is provided is taken as the Z-axis direction (a third direction); one direction parallel to the major surface is taken as an X-axis direction (a first direction); and a direction parallel to the major surface and perpendicular to the X-axis direction is taken as a Y-axis direction (a second direction).

For example, multiple word lines WL and multiple active areas AA are provided in the cell array region CA. Each of the multiple word lines WL has, for example, a band configuration extending along the Y-axis direction. Each of the multiple active areas AA has, for example, a band configuration extending along the X-axis direction. In other words, the multiple word lines WL and the multiple active areas AA are provided in a lattice configuration. The width (the length along the X-axis direction) of each of the multiple word lines WL is, for example, 30 nanometers (the nm). The spacing between the multiple word lines WL is, for example, 30 nm. The width (the length along the Y-axis direction) of each of the multiple active areas AA is, for example, 30 nm. The spacing between the multiple active areas AA is, for example, 30 nm. One NAND column CL may include a set of, for example, 64 word lines WL.

A bit line contact BC is provided at one end of the NAND column CL; and a source line contact SC is provided at one other end of the NAND column CL. In the NAND column CL, a drain-side selection gate SGD is provided between the bit line contact BC and the word lines WL; and a source-side selection gate SGS is provided between the source line contact SC and the word lines WL.

As illustrated in FIG. 3A and FIG. 3B, a semiconductor layer 11 is divided into multiple regions on a major surface 11ms side of the semiconductor layer 11 by an element isolation insulating film 13. The semiconductor layer 11 may include, for example, monocrystalline silicon.

In other words, multiple semiconductor regions, e.g., a first semiconductor layer 11a and a second semiconductor layer 11b, are provided on the major surface 11ms side of the semiconductor layer 11. The first semiconductor layer 11a and the second semiconductor layer 11b are electrically isolated by the element isolation insulating film 13. The element isolation insulating film 13 may include, for example, silicon oxide.

The first semiconductor layer 11a and the second semiconductor layer 11b correspond to the active areas AA. The first semiconductor layer 11a and the second semiconductor layer 11b extend along the X-axis direction.

Multiple control gate interconnects 45 extending in the Y-axis direction are provided above the first semiconductor layer 11a and the second semiconductor layer 11b. The control gate interconnect 45 corresponds to the word line WL.

For convenience of description hereinbelow, the direction from the semiconductor layer 11 (the silicon substrate) toward the control gate interconnect 45 (the +Z-axis direction) is taken as the upward direction.

A tunneling insulating film 12 is provided on the portions of the semiconductor layer 11 (e.g., the first semiconductor layer 11a and the second semiconductor layer 11b) intersected three-dimensionally by the control gate interconnect 45. A floating gate electrode 20 is provided on the tunneling insulating film 12. The tunneling insulating film 12 may include, for example, silicon oxide. The floating gate electrode 20 may include, for example, polysilicon.

The upper portion of the element isolation insulating film 13 is disposed at the lower portion between the floating gate electrodes 20. The upper surface of the element isolation insulating film 13 is positioned higher than the lower surface of the floating gate electrode 20. The upper surface of the element isolation insulating film 13 is positioned lower than the upper surface of the floating gate electrode 20. The element isolation insulating film 13 electrically isolates the multiple floating gate electrodes 20 from each other while electrically isolating the multiple semiconductor layers 11 from each other.

An inter-layer insulating film 30 (a control gate-floating gate insulating film) is provided on the upper surface of the floating gate electrode 20, the portion of the side surface of the floating gate electrode 20 higher than the upper surface of the element isolation insulating film 13, and the portion of the upper surface of the element isolation insulating film 13 where the word line WL intersects. The inter-layer insulating film 30 is provided, for example, continuously to cover the upper surface of the floating gate electrode 20, the portion of the side surface of the floating gate electrode 20 higher than the upper surface of the element isolation insulating film 13, and the portion of the upper surface of the element isolation insulating film 13 where the word line WL intersects. The inter-layer insulating film 30 includes, for example, silicon oxide.

For example, the inter-layer insulating film 30 includes a first side wall portion 30as contacting the side wall of a first floating gate electrode 20a on a second floating gate electrode 20b side, a first apical portion 30at contacting the upper surface of the first floating gate electrode 20a, a second side wall portion 30bs contacting the side wall of the second floating gate electrode 20b on the first floating gate electrode 20a side, and a second apical portion 30bt contacting the upper surface of the second floating gate electrode 20b.

A control gate electrode 42 is provided to cover the inter-layer insulating film 30. The control gate electrode 42 includes a portion between the floating gate electrodes 20 (a buried conductive portion 40 buried between the floating gate electrodes 20). The control gate electrode 42 further includes a floating gate electrode upper conductive portion 41 (including a first floating gate electrode upper conductive portion 41a and a second floating gate electrode upper conductive portion 41b) provided on the floating gate electrodes 20 and the buried conductive portions 40. The buried conductive portion 40 and the floating gate electrode upper conductive portion 41 are provided integrally. The buried conductive portion 40 and the floating gate electrode upper conductive portion 41 may include, for example, polysilicon.

An upper layer control gate electrode 60 is provided on the control gate electrode 42 (specifically, the floating gate electrode upper conductive portion 41). The upper layer control gate electrode 60 may include, for example, polysilicon and/or silicide.

The floating gate electrode upper conductive portion 41 of the control gate electrode 42 and the upper layer control gate electrode 60 extend along the Y-axis direction. The floating gate electrode upper conductive portion 41 and the upper layer control gate electrode 60 correspond to, for example, the control gate interconnect 45 (i.e., the word line WL).

The buried conductive portion 40 of the control gate electrode 42 includes a core conductive portion 50 having a conductive material filled into a void.

The core conductive portion 50 may include polysilicon similarly to the buried conductive portion 40. The core conductive portion 50 may include a silicide such as WSi. The core conductive portion 50 also may include a metal nitride such as TiN. The core conductive portion 50 may include a metal. The core conductive portion 50 may include not only a single-layer film but also a stacked film including a semiconductor, a metal, an alloy, a silicide, and a metal compound (including a metal nitride).

The core conductive portion 50 is formed by a void forming in the buried conductive portion 40 when forming the buried conductive portion 40 between the floating gate electrodes 20 as described below and by filling a conductive material into the void. Cases may exist where the boundary between the core conductive portion 50 and the buried conductive portion 40 is distinct and where the boundary is indistinct according to the materials and the formation conditions of the core conductive portion 50 and the buried conductive portion 40.

As illustrated in FIG. 3B, an impurity diffusion region 11d is provided in the semiconductor layer 11 in the region between the floating gate electrodes 20 proximal to the upper surface of the semiconductor layer 11. A floating gate memory transistor is formed of each of the semiconductor layers 11, the tunneling insulating film 12, the floating gate electrode 20, the inter-layer insulating film 30, the control gate electrode 42, and the impurity diffusion regions 11d. The impurity diffusion regions 11d are shared by the floating gate memory transistors arranged in the X-axis direction.

The buried conductive portion 40, which is a portion of the control gate electrode 42, is provided between the floating gate electrodes 20. The buried conductive portion 40 functions electrically with the floating gate electrode upper conductive portion 41 as a control gate. Thereby, the surface area where the control gate electrode 42 and the floating gate electrode 20 face each other with the inter-layer insulating film 30 interposed increases; and an electrical capacitance C1 between the control gate electrode 42 and the floating gate electrode 20 increases.

To obtain good programming characteristics in NAND flash memory, it is desirable for the electrical capacitance Cl to be not less than about 1.5 times an electrical capacitance C2 between the floating gate electrode 20 and the semiconductor layer 11 (the silicon substrate).

To suppress leak current, the thickness of the inter-layer insulating film 30 is set to be sufficiently thick compared to the tunneling insulating film 12. Therefore, to increase the electrical capacitance C1 to the desired large value, the surface area where the control gate electrode 42 and the floating gate electrode 20 face each other is increased by employing the configuration in which the buried conductive portion 40 is provided in the control gate electrode 42.

Herein, the proportion of the electrical capacitance C1 between the control gate electrode 42 and the floating gate electrode 20 to the total of the electrical capacitance C1 and the electrical capacitance C2 between the floating gate electrode 20 and the semiconductor layer 11 (the silicon substrate) (C1/(C1+C2)) is called the coupling ratio. The programming characteristics are good when the coupling ratio is high.

The electrical capacitance C1 increases, the coupling ratio increases, and the cell programming characteristics improve as the lower surface of the control gate electrode 42 between the floating gate electrodes 20 (the lower surface of the buried conductive portion 40) is positioned downward.

On the other hand, in the case where the lower surface of the control gate electrode 42 (the lower surface of the buried conductive portion 40) is positioned excessively downward, a leak current occurs between the control gate electrode 42 and the semiconductor layer 11 (the silicon substrate).

Based on the aspects recited above, the position of the lower surface of the control gate electrode 42 (the lower surface of the buried conductive portion 40) is set appropriately.

As illustrated in FIG. 3B, an inter-layer insulating layer is provided between the tunneling insulating films 12, between the floating gate electrodes 20, between the inter-layer insulating films 30, between the control gate electrodes 42 (the floating gate electrode upper conductive portions 41), and between the upper layer control gate electrodes 60 that are mutually adjacent along the X-axis direction. The inter-layer insulating layer 70 may include, for example, silicon oxide.

The method for manufacturing the semiconductor memory device according to the embodiment will now be described.

In the method for manufacturing the semiconductor memory device in the embodiment as illustrated in FIG. 1, multiple protruding portions having band configurations used to form the floating gate electrodes 20 (the electrodes) are formed on the major surface 11ms of the semiconductor layer 11 to extend along the first direction (e.g., the X-axis direction) parallel to the major surface 11ms (step S110).

An inter-layer insulating film is formed to cover the multiple protruding portions and the inner surface of a trench between the multiple protruding portions (step S120).

A buried conductive portion is formed by filling a first conductive material into a space inside the trench recited above with the inter-layer insulating film provided around the space (step S130).

Then, a buried conductive portion side surface of the buried conductive portion along the Y-axis direction (the second direction parallel to the major surface 11ms and non-parallel to the first direction) is exposed by dividing the buried conductive portion along the X-axis direction (step S140).

At this time, a side surface of the protruding portion recited above along the Y-axis direction (a second protruding portion side surface) and an inter-layer insulating film side surface of the inter-layer insulating film along the Y-axis direction are exposed by dividing the multiple protruding portions and the inter-layer insulating film recited above along the X-axis direction when dividing the buried conductive portion.

Then, a second conductive material is filled into the void of the buried conductive portion exposed at the buried conductive portion side surface (step S150). The second conductive material may be the same as the first conductive material or may be different from the first conductive material.

Continuing, a portion (an unnecessary portion) of the second conductive material is removed (step S160). For example, the second conductive material formed on the second protruding portion side surface, on the upper surface of the multiple protruding portions, on the inter-layer insulating film side surface, on the upper surface of the inter-layer insulating film, on the buried conductive portion side surface, and on the upper surface of the buried conductive portion 40 when filling the second conductive material into the void is removed.

Thus, in the manufacturing method according to the embodiment, the core conductive portion 50 is formed by filling the conductive material into the void made in the buried conductive portion 40. Thereby, a semiconductor memory device can be manufactured in which the occurrence of operation errors can be suppressed.

Specific examples of the method for manufacturing the semiconductor memory device according to the embodiment will now be described.

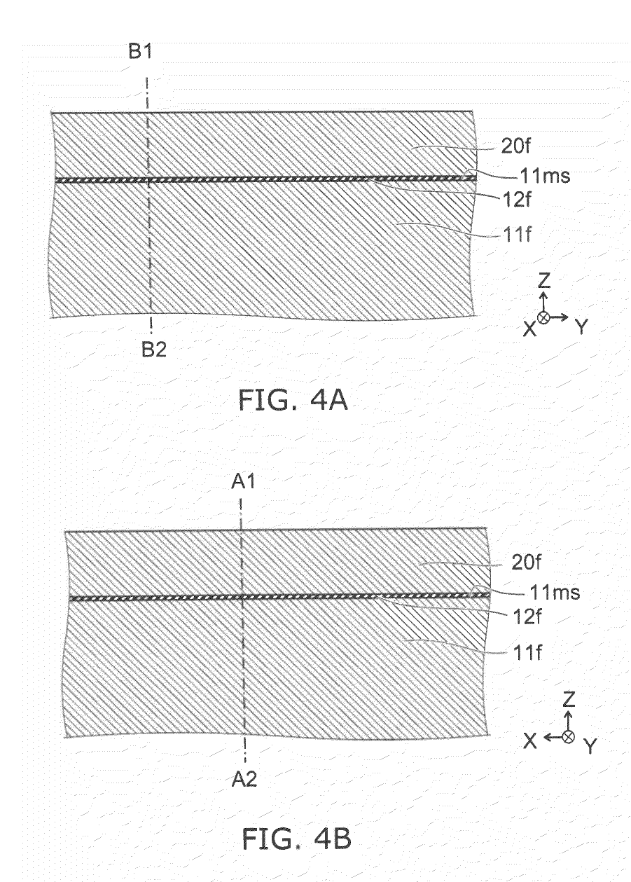

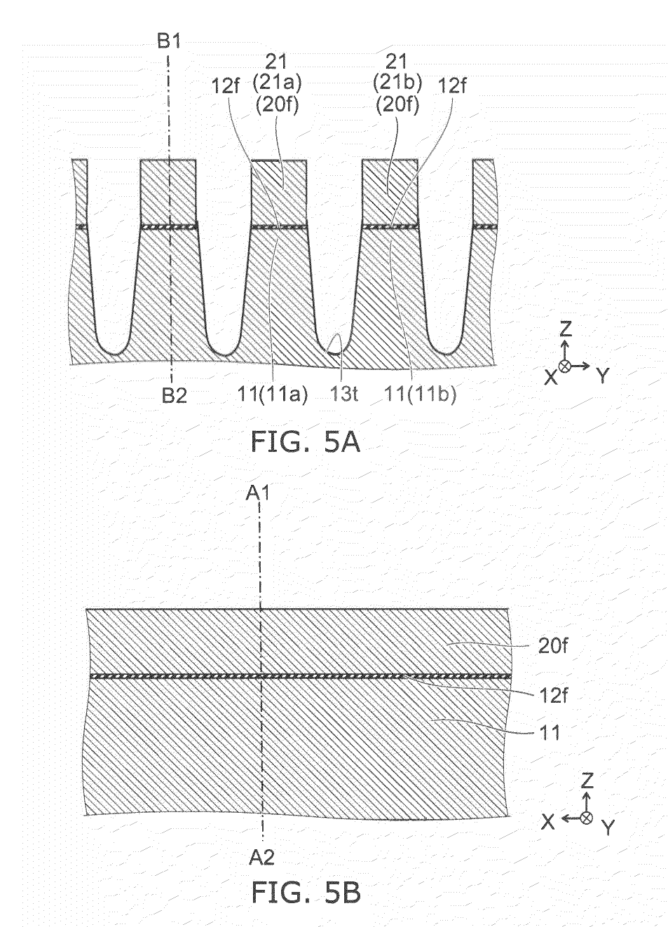

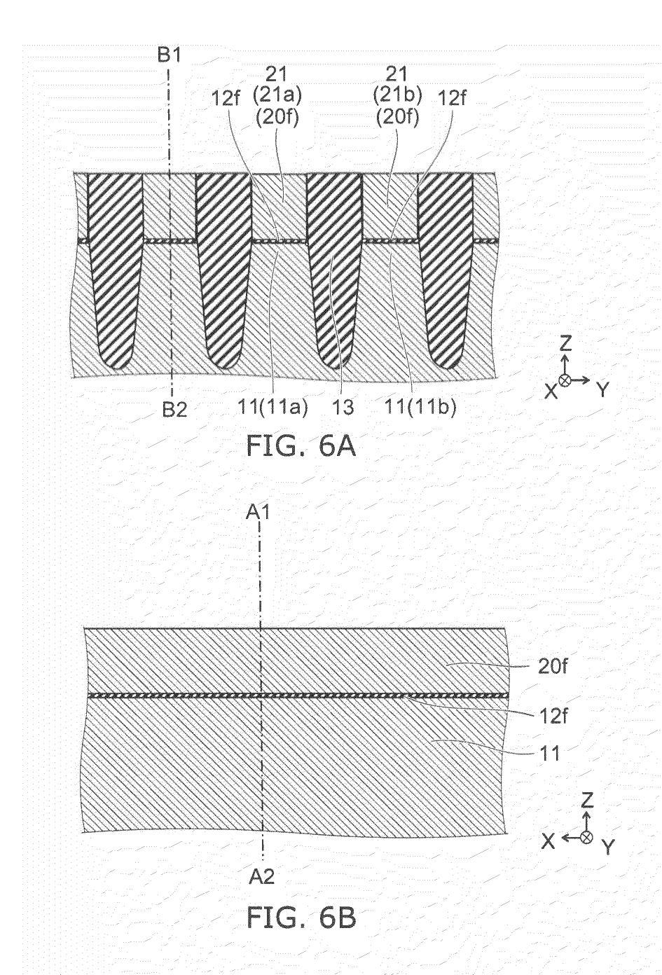

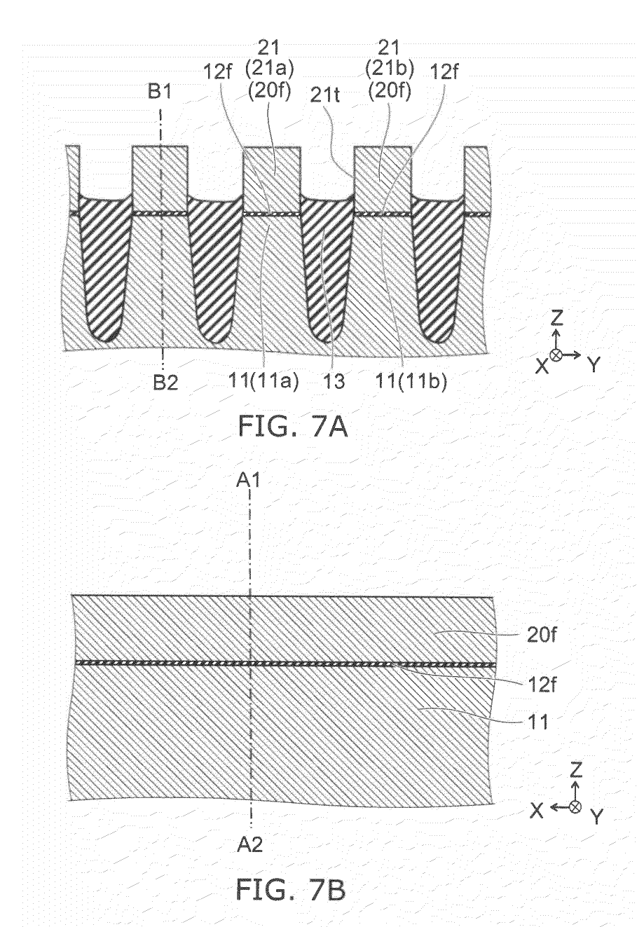

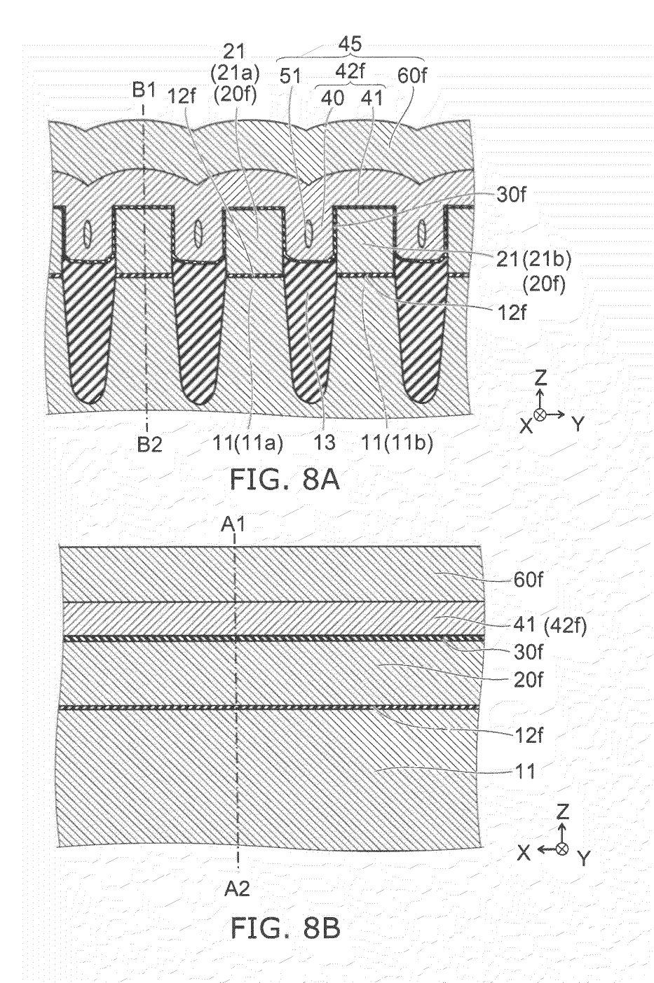

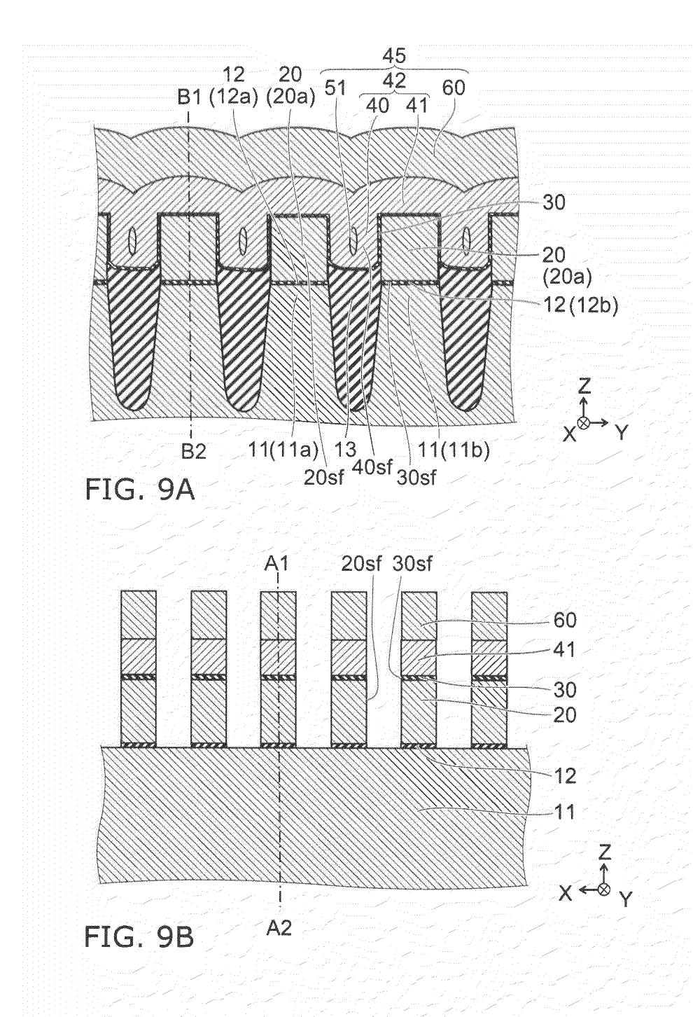

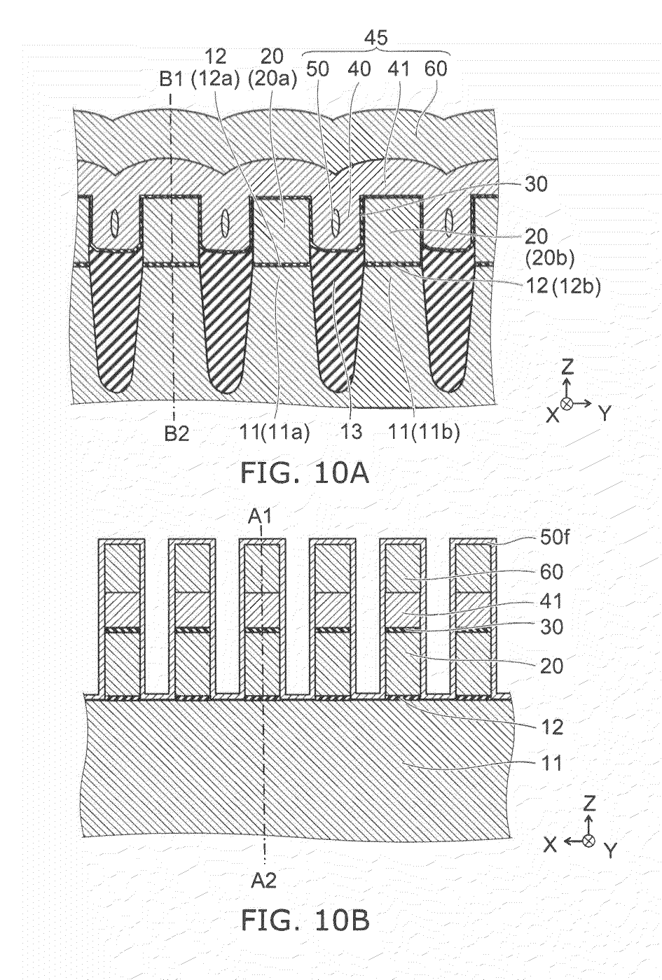

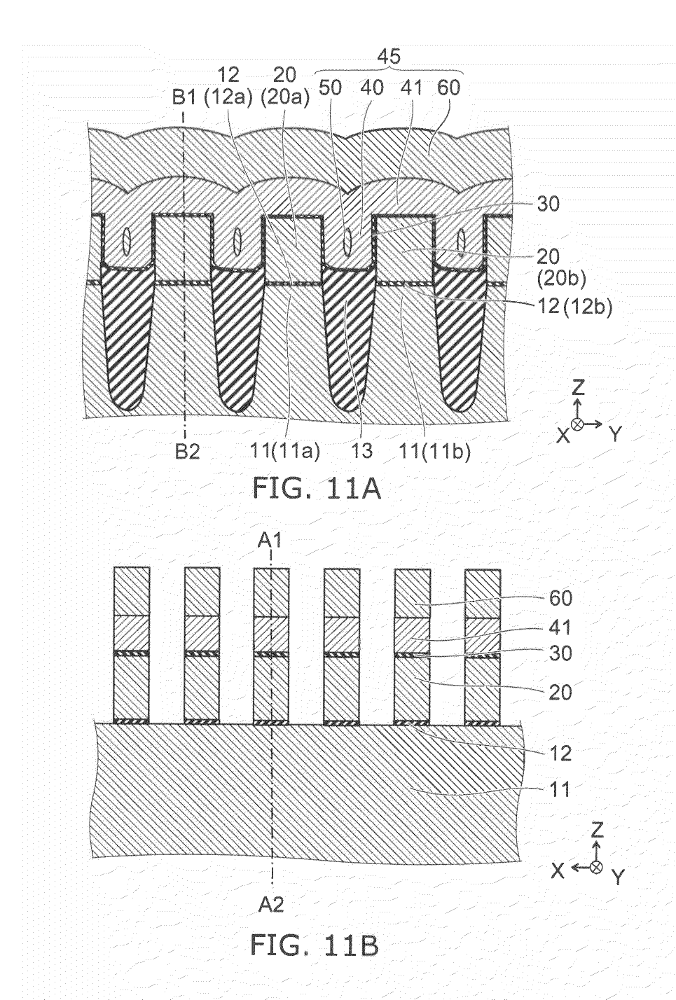

FIG. 4A, FIG. 4B, FIG. 5A, FIG. 5B, FIG. 6A, FIG. 6B, FIG. 7A, FIG. 7B, FIG. 8A, FIG. 8B, FIG. 9A, FIG. 9B, FIG. 10A, FIG. 10B, FIG. 11A, and FIG. 11B are schematic cross-sectional views in order of the processes, illustrating the method for manufacturing the semiconductor memory device according to the first embodiment.

FIG. 4A, FIG. 5A, FIG. 6A, FIG. 7A, FIG. 8A, FIG. 9A, FIG. 10A, and FIG. 11A are cross-sectional views corresponding to the cross section along line A1-A2 of FIG. 2; and FIG. 4B, FIG. 5B, FIG. 6B, FIG. 7B, FIG. 8B, FIG. 9B, FIG. 10B, and FIG. 11B are cross-sectional views corresponding to the cross section along line B1-B2 of FIG. 2.

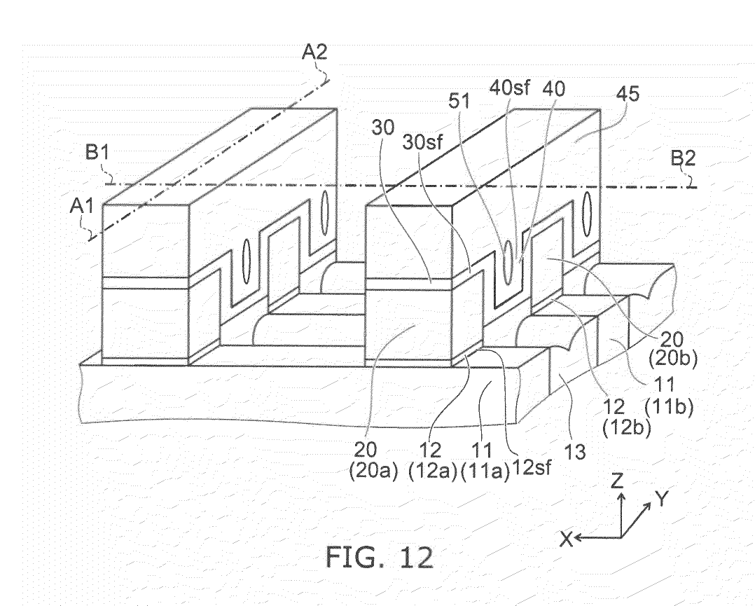

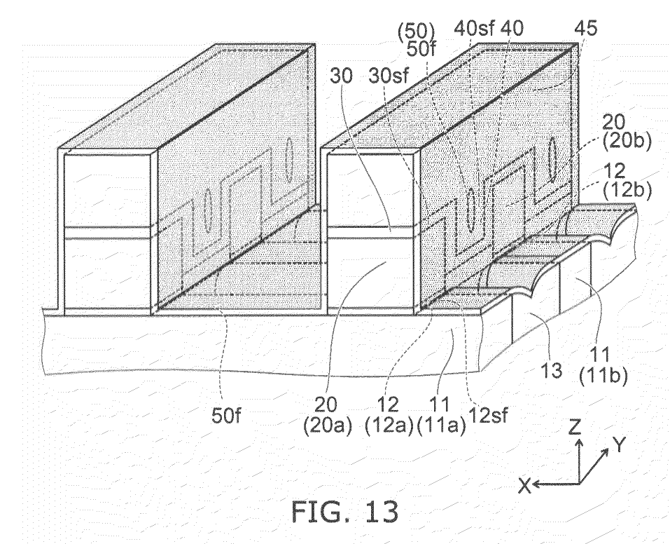

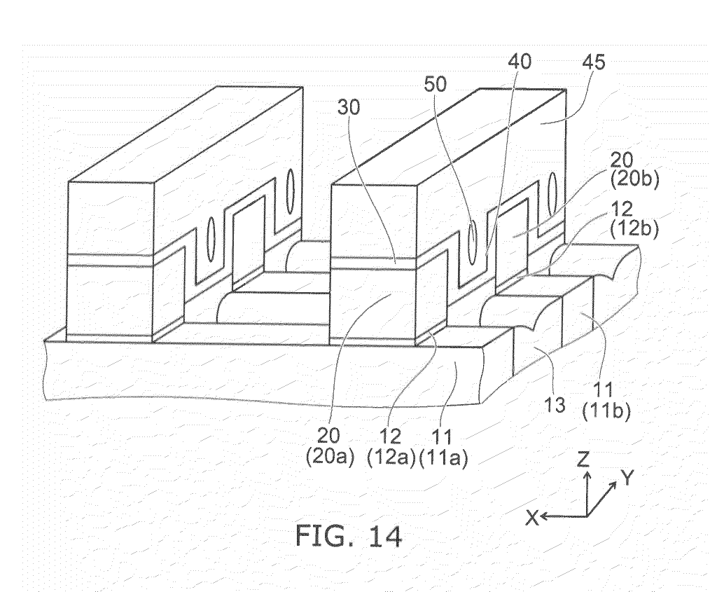

FIG. 12, FIG. 13, and FIG. 14 are schematic perspective views in order of the processes, illustrating the method for manufacturing the semiconductor memory device according to the first embodiment.

FIG. 12 corresponds to the process illustrated in FIG. 9A and FIG. 9B; FIG. 13 corresponds to the process illustrated in FIG. 10A and FIG. 10B; and FIG. 14 corresponds to the process illustrated in FIG. 11A and FIG. 11B.

As illustrated in FIG. 4A and FIG. 4B, an insulating film 12f used to form the tunneling insulating film 12 is formed on the major surface 11ms of the semiconductor layer 11 (e.g., a silicon substrate); and a floating gate film 20f used to form the floating gate electrode 20 is formed thereon. The floating gate film 20f may include, for example, polysilicon.

As illustrated in FIG. 5A and FIG. 5B, multiple trenches 13t are made by patterning the semiconductor layer 11, the insulating film 12f, and the floating gate film 20f using lithography and etching. The trench 13t extends along the X-axis direction. Thereby, the multiple active areas AA extending along the X-axis direction are formed by the portions of the semiconductor layer 11 on the major surface 11ms side being divided. In other words, for example, the first semiconductor layer 11a, the second semiconductor layer 11b, etc., are formed.

The insulating film 12f is patterned into band configurations extending in the X-axis direction. The floating gate film 20f also is patterned into band configurations extending in the X-axis direction. The floating gate film 20f patterned into the band configurations corresponds to multiple protruding portions 21 used to form the multiple floating gate electrodes 20. The protruding portions 21 (e.g., a first protruding portion 21a and a second protruding portion 21b) have band configurations.

This process corresponds to step S110 recited above.

The aspect ratio of the trench 13t is high; and the depth of the trench 13t (the depth along the Z-axis direction perpendicular to the major surface 11ms) is deeper than the width of the trench 13t along the Y-axis direction.

The height of the protruding portion 21 (the length along the Z-axis direction) is greater than the width of the protruding portion 21 (the length along the Y-axis direction).

As illustrated in FIG. 6A and FIG. 6B, an insulating film used to form the element isolation insulating film 13 (e.g., a silicon oxide film) is formed on the floating gate film 20f and in the interior of the trench 13t; and subsequently, the floating gate film 20f is exposed by removing the insulating film on the floating gate film 20f and planarizing. For example, CVD (Chemical Vapor Deposition) or SOG (Spin On Glass) may be used in the formation of the insulating film. For example, CMP (Chemical Mechanical Polishing) may be used in the removal of the insulating film and the planarizing recited above. The multiple active areas AA (e.g., the first semiconductor layer 11a and the second semiconductor layer 11b) are electrically isolated by the element isolation insulating film 13 being filled into the trench 13t.

As illustrated in FIG. 7A and FIG. 7B, the upper surface of the element isolation insulating film 13 is caused to be positioned lower than the upper surface of the floating gate film 20f (the upper surface of the protruding portion 21) by causing the element isolation insulating film 13 to recede. For example, etching is performed at conditions at which the element isolation insulating film 13 is selectively removed and the floating gate film 20f is not easily removed. Thereby, a trench 21t is made between the multiple protruding portions 21.

Thus, the upper surface of the element isolation insulating film 13 is disposed between the upper surface of the floating gate film 20f and the lower surface of the floating gate film 20f. Thereby, as described above, good programming characteristics can be ensured; and the current leakage between the control gate electrode 42 and the semiconductor layer 11 is suppressed.

As illustrated in FIG. 8A and FIG. 8B, an insulating film 30f (e.g., a silicon oxide film) used to form the inter-layer insulating film 30 is formed; a conductive film 42f (e.g., a polysilicon film) used to form the control gate electrode 42 is formed; and a conductive film 60f (e.g., a polysilicon film or a silicide film) used to form the upper layer control gate electrode 60 is formed. For example, diffusion deposition or CVD may be used to form the insulating film 30f, the conductive film 42f, and the conductive film 60f. The portion of the conductive film 42f between the protruding portions 21 used to form the floating gate electrode 20 (e.g., between the first protruding portion 21a and the second protruding portion 21b) becomes the buried conductive portion 40; and the portion of the conductive film 42f on the protruding portion 21 becomes the floating gate electrode upper conductive portion 41.

This process corresponds to step S120 of forming the inter-layer insulating film (the insulating film 30f) and step S130 of forming the buried conductive portion 40.

At this time, as illustrated in FIG. 8A, a void 51 is formed in the buried conductive portion 40.

Although the void 51 does not easily form, for example, in the case where the spacing between the protruding portions 21 used to form the floating gate electrodes 20 is sufficiently wide compared to the height of the protruding portion 21, the void 51 occurs easily if the side wall of the protruding portion 21 is tilted, etc., in the case where the element is downscaled and the spacing between the protruding portions 21 is narrow compared to the height of the protruding portion 21 or in the case where the side wall of the protruding portion 21 is substantially perpendicular to sufficiently ensure the size of the floating gate electrode 20.

In the semiconductor memory device in which the manufacturing method according to the embodiment is applied, the element is downscaled and the void 51 forms in the buried conductive portion 40. The side wall of the protruding portion 21 is substantially perpendicular to ensure good operations; and the void 51 forms in the buried conductive portion 40. The void 51 has a pipe configuration extending in the X-axis direction along the buried conductive portion 40 extending in the X-axis direction. Or, multiple voids 51 arranged in the X-axis direction form inside the buried conductive portion 40. There are cases where the void 51 has one continuous pipe configuration; and there are cases where the void 51 is multiple independent spaces.

The diameter of the void 51 is, for example, about 3 nm. In the case where the cross section of the void 51 (the cross section when cut by the Y-Z plane) is flattened circular, the diameter of the flattened circle in the minor-axis direction (the minor diameter) is, for example, about 3 nm.

In a peripheral circuit unit, for example, after the formation of the conductive film 42f recited above, lithography and etching are performed to form transistor gates by utilizing the conductive films including the conductive film 42f and the floating gate film 20f; and subsequently, the formation of the conductive film 60f recited above is performed.

As illustrated in FIG. 9A and FIG. 9B, the conductive film 60f, the conductive film 42f, the insulating film 30f, the floating gate film 20f, and the insulating film 12f are divided along the X-axis direction. Thereby, the upper layer control gate electrode 60 is formed from the conductive film 60f in a band configuration extending in the Y-axis direction; and the control gate electrode 42 (the floating gate electrode upper conductive portion 41) is formed from the conductive film 42f in a band configuration extending in the Y-axis direction. Then, the floating gate electrode 20 is formed from the floating gate film 20f in a columnar configuration. The inter-layer insulating film 30 is formed to cover the upper surface of the floating gate electrode 20 and the side surface of the floating gate electrode 20 along the X-axis direction. The tunneling insulating film 12 is formed from the insulating film 12f.

In this process, the multiple protruding portions 21, the inter-layer insulating film (the insulating film 30f), and the buried conductive portion 40 are divided along the X-axis direction.

Thereby, as illustrated in FIG. 9A, FIG. 9B, and FIG. 12, a second protruding portion side surface 20sf of the protruding portion 21 (the floating gate electrode 20) along the Y-axis direction, the inter-layer insulating film side surface 30sf of the inter-layer insulating film 30 (the insulating film 30f) along the Y-axis direction, and a buried conductive portion side surface 40sf of the buried conductive portion 40 along the Y-axis direction are exposed. In other words, this process corresponds to step S140.

In the manufacturing method, step S150 of filling the second conductive material into the void 51 of the buried conductive portion 40 exposed at the buried conductive portion side surface 40sf is performed, for example, as follows.

As illustrated in FIG. 10A, FIG. 10B, and FIG. 13, a buried film 50f of the second conductive material is formed. The buried film 50f may include, for example, polysilicon. Thereby, the core conductive portion 50 is formed in the void 51 by the buried film 50f being formed inside the void 51 of the buried conductive portion 40 exposed at the buried conductive portion side surface 40sf.

The thickness of the buried film 50f may be, for example, about 2 nm. Because the diameter of the void 51 recited above is, for example, 3 nm, the polysilicon is filled into the void 51 by the void 51 being filled with the polysilicon film by the buried film 50f being formed with a thickness of about 2 nm.

A film formation method having high fillability is employed in the formation of the buried film 50f. For example, film formation by CVD having a reaction-controlled film formation condition or film formation by ALD (Atomic Layer Deposition) is applied in, for example, the film formation of the polysilicon of the buried film 50f.

Subsequently, as illustrated in FIG. 11A, FIG. 11B, and FIG. 14, a portion (an unnecessary portion) of the buried film 50f is removed. In other words, the buried film 50f formed on the second protruding portion side surface 20sf, on the upper surface of the multiple protruding portions 21, on the inter-layer insulating film side surface 30sf, on the upper surface of the inter-layer insulating film 30, on the buried conductive portion side surface 40sf, and on the upper surface of the buried conductive portion 40 in step S150 recited above (the process of filling the buried film 50f of the second conductive material into the void 51) is removed. For example, wet etching is used in the removal of the unnecessary portions of the buried film 50f. Thereby, the buried film 50f is caused to recede 2 nm. Thereby, the unnecessary portions of the buried film 50f are removed. Then, although the buried film 50f filled into the interior of the void 51 recedes 2 nm, the buried film 50f of the inner portion of the void 51 remains as-is. Thereby, the core conductive portion 50 is formed in which substantially the entire region of the interior of the void 51 is filled with the conductive material.

The insulation between the floating gate electrode 20 and the control gate electrode 42 (and the upper layer control gate electrode 60), the insulation between the semiconductor layer 11 (the silicon substrate) and the floating gate electrode 20, and the insulation between the semiconductor layers 11 (e.g., the first semiconductor layer 11a, the second semiconductor layer 11b, etc.) can be ensured by removing the unnecessary portions of the buried film 50f.

In the case where polysilicon is used as the buried film 50f, wet etching using, for example, an alkaline solution including ammonia or choline may be used in the removal of the unnecessary portions of the buried film 50f. Also, dry etching, etc., having high isotropy may be used in the removal of the unnecessary portions of the buried film 50f.

Subsequently, the impurity diffusion region 11d is formed, for example, by introducing an impurity into the semiconductor layer 11 using the upper layer control gate electrode 60 and the control gate electrode 42 as a mask. Subsequently, the inter-layer insulating layer 70 is formed by filling an insulating material between the tunneling insulating films 12, between the floating gate electrodes 20, between the inter-layer insulating films 30, between the control gate electrodes 42 (the floating gate electrode upper conductive portions 41), and between the upper layer control gate electrodes 60 and by planarizing.

Thereby, the semiconductor memory device 110 illustrated in FIG. 2, FIG. 3A, and FIG. 3B is manufactured.

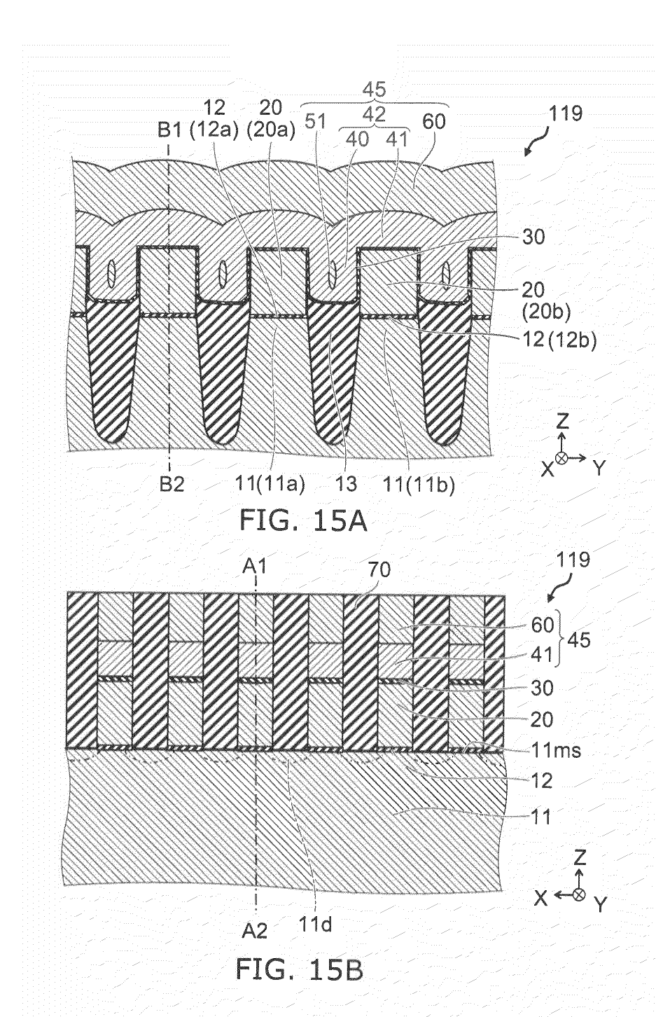

FIG. 15A and FIG. 15B are schematic cross-sectional views illustrating the configuration of a semiconductor memory device manufactured using a method for manufacturing a semiconductor memory device of a reference example.

Namely, FIG. 15A is a cross-sectional view along line A1-A2 of FIG. 15B; and FIG. 15B is a cross-sectional view along line B1-B2 of FIG. 15A.

In the semiconductor memory device 119 of the reference example as illustrated in FIG. 15A and FIG. 15B, the void 51 exists in the buried conductive portion 40. In the method for manufacturing the semiconductor memory device 119 of the reference example, step S150 (and step S160) illustrated in FIG. 1 are not implemented.

In other words, the semiconductor memory device 119 is constructed by forming the impurity diffusion region 11d and the inter-layer insulating layer 70 without filling the conductive material into the void 51 made in the buried conductive portion 40 after the process described in regard to FIG. 9A, FIG. 9B, and FIG. 12 (the formation of the upper layer control gate electrode 60, the control gate electrode 42, the inter-layer insulating film 30, the floating gate electrode 20, and the tunneling insulating film 12).

Because the void 51 remains in the buried conductive portion 40 of the control gate electrode 42 in the semiconductor memory device 119 of the reference example, the buried conductive portion 40 does not function as an electrode; depletion of the buried conductive portion 40 occurs; and programming defects occur. Thus, operation errors occur easily in the semiconductor memory device 119.

Conversely, because the core conductive portion 50 is formed by the conductive material being buried in the void 51 in the semiconductor memory device 110 manufactured using the manufacturing method according to the embodiment, the depletion is suppressed; the entire buried conductive portion 40 operates as an electrode; and good programming characteristics are obtained.

Although it is conceivable to use a method in which the void 51 does not occur easily in the buried conductive portion 40 by providing the protruding portion 21 used to form the floating gate electrode 20 with a tapered configuration (a configuration of the protruding portion 21 having a narrower width at the upper portion than at the lower portion), in such a case, the amount of charge stored in the floating gate electrode 20 decreases because the volume of the floating gate electrode 20 decreases. Therefore, in such a method, the programming characteristics and/or the read-out characteristics worsen easily. Further, the data retention characteristics worsen easily because the stored amount of charge changes over time. In such a structure, there is also a side effect of electric field concentration being caused because the tip of the floating gate electrode 20 is finer in this configuration.

Conversely, in the semiconductor memory device 110 manufactured using the manufacturing method according to the embodiment, normal operation as an electrode is possible by subsequently filling the conductive material into the void 51 that was made even in the case where the protruding portion 21 used to form the floating gate electrode 20 has a substantially vertical configuration in which the void 51 occurs easily. Thereby, good programming characteristics, good read-out characteristics, and good data retention characteristics are obtained because the volume of the floating gate electrode 20 can be set to the necessary value.

By employing the method for manufacturing the semiconductor memory device according to the embodiment, various constraints considering the occurrence of the void 51 can be relaxed and a semiconductor memory device having a lower cost and a higher speed can be realized even in the case where downscaling progresses to reduce costs and/or increase the element speed, the element configuration has a high aspect ratio, and the void 51 occurs easily in the buried conductive portion 40.

Moreover, although the void 51 occurs more easily in the case where the protruding portion 21 has a reverse taper (a configuration in which the width of the protruding portion 21 is wider than that of the lower portion), normal operations can be realized by employing the manufacturing method to change the void 51 that occurred into the core conductive portion 50 to accommodate even the case of a reverse taper.

As recited above, polysilicon can be used as the first conductive material and the second conductive material. In such a case, the filling of the first conductive material (step S130 which is the formation of the buried conductive portion 40) may include a process of forming a first amorphous silicon film; and the filling of the second conductive material (step S150) may include a process of forming a second amorphous silicon film.

Then, the filling of the second conductive material (step S150) may further include a process of polycrystalizing the first amorphous silicon film and the second amorphous silicon film. Or, the manufacturing method may further include a process of polycrystalizing the first amorphous silicon film and the second amorphous silicon film after the removal of a portion (an unnecessary portion) of the film of the second conductive material (step S160).

The filling of the first conductive material (step S130) also may include a process of polycrystalline-siliconizing the first amorphous silicon film after the first amorphous silicon film is formed. Then, the filling of the second conductive material (step S150) may include a process of forming the second amorphous silicon film. The filling of the second conductive material (step S150) may further include a process of polycrystalizing the second amorphous silicon film. Or, the manufacturing method may further include a process of polycrystalizing the second amorphous silicon film after the removal of a portion (an unnecessary portion) of the film of the second conductive material (step S160).

Further, in the case where the first conductive material is polysilicon, a silicide such as WSi, a metal nitride such as TiN, or a metal may be used as the second conductive material. The core conductive portion 50 may include a metal. Thus, the filling of the first conductive material (step S130) may include a process of forming an amorphous silicon film or a polycrystalline silicon film; and the filling of the second conductive material may include a process of forming a metal film or a metal compound film.

The first conductive material may include a silicide. The first conductive material may include a metal.

The filling of the first conductive material (step S130) may include the formation of a stacked film of a polysilicon film and a silicide film. In such a case, the filling of the second conductive material (step S150) may include the formation of at least one selected from a polysilicon film and a silicide film.

The filling of the first conductive material (step S130) may include the formation of a stacked film of a polysilicon film and a metal film. In such a case, the filling of the second conductive material (step S150) may include the formation of at least one selected from a polysilicon film and a metal film.

The filling of the first conductive material (step S130) may include the formation of a stacked film of a silicide film and a metal film. In such a case, the filling of the second conductive material (step S150) may include the formation of at least one selected from a silicide film and a metal film.

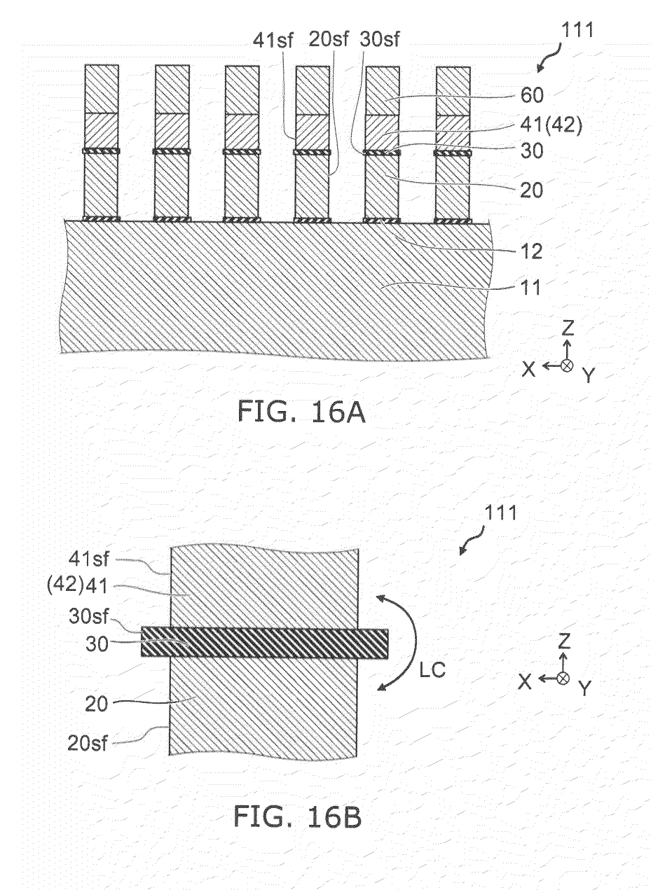

FIG. 16A and FIG. 16B are schematic cross-sectional views illustrating the configuration of another semiconductor memory device manufactured using the method for manufacturing the semiconductor memory device according to the first embodiment.

Namely, FIG. 16A is a cross-sectional view corresponding to the cross section along line B1-B2 of FIG. 2. However, the inter-layer insulating layer 70 is not illustrated for easier viewing. A portion of FIG. 16A is enlarged in FIG. 16B.

In the semiconductor memory device 111 as illustrated in FIG. 16A, the second protruding portion side surface 20sf of the protruding portion 21 (the floating gate electrode 20) along the Y-axis direction and a floating gate electrode upper conductive portion side surface 41sf of the floating gate electrode upper conductive portion 41 of the control gate electrode 42 along the Y-axis direction are recessed from the inter-layer insulating film side surface 30sf of the inter-layer insulating film 30 (the insulating film 30f) along the Y-axis direction.

In such a configuration, for example, the protruding portion 21 (the floating gate electrode 20) and the buried conductive portion 40 are formed by being etched with the buried film 50f in the processing of step S160 of removing the portion (the unnecessary portion) of the buried film 50f. In other words, the etching rate of the inter-layer insulating film 30 is lower than the etching rates of the protruding portion 21 (the floating gate electrode 20) and the buried conductive portion 40 in the processing recited above in the case where the protruding portion 21 (the floating gate electrode 20), the buried conductive portion 40, and the buried film 50f are polysilicon and the inter-layer insulating film 30 is silicon oxide. Thereby, the second protruding portion side surface 20sf of the protruding portion 21 (the floating gate electrode 20) and the floating gate electrode upper conductive portion side surface 41sf of the floating gate electrode upper conductive portion 41 are recessed from the inter-layer insulating film side surface 30sf of the inter-layer insulating film 30.

As illustrated in FIG. 16B, a leak current LC due to the electric field between the floating gate electrode 20 and the control gate electrode 42 can be suppressed by the side surface (the second protruding portion side surface 20sf) of the floating gate electrode 20 and the side surface (the floating gate electrode upper conductive portion side surface 41sf) of the control gate electrode 42 being recessed from the side surface (the inter-layer insulating film side surface 30sf) of the inter-layer insulating film 30. Thereby, the programming characteristics can be improved.

Thus, it is more desirable for the side surface (the second protruding portion side surface 20sf) of the floating gate electrode 20 and the side surface (the floating gate electrode upper conductive portion side surface 41sf) of the control gate electrode 42 to be recessed from the side surface (the inter-layer insulating film side surface 30sf) of the inter-layer insulating film 30.

Accordingly, in step S160, it is desirable to etch the side surface of the protruding portion 21 used to form the floating gate electrode 20 and the side surface of the floating gate electrode upper conductive portion 41 portion used to form the control gate electrode 42 when removing the buried film 50f formed when filling the second conductive material into the void 51.

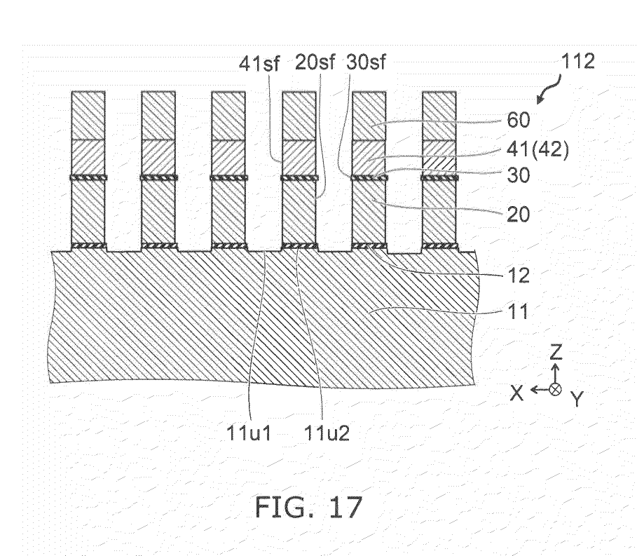

FIG. 17 is a schematic cross-sectional view illustrating the configuration of another semiconductor memory device manufactured using the method for manufacturing the semiconductor memory device according to the first embodiment.

Namely, FIG. 17 is a cross-sectional view corresponding to the cross section along line B1-B2 of FIG. 2. However, the inter-layer insulating layer 70 is not illustrated for easier viewing.

As illustrated in FIG. 17, in the semiconductor memory device 112 as well, the second protruding portion side surface 20sf of the protruding portion 21 and the floating gate electrode upper conductive portion side surface 41sf of the floating gate electrode upper conductive portion 41 are recessed from the inter-layer insulating film side surface 30sf of the inter-layer insulating film 30.

An upper surface 11u1 of the semiconductor layer 11 corresponding to the region between the floating gate electrodes 20 mutually adjacent along the X-axis direction is positioned lower than an upper surface 11u2 of the semiconductor layer 11 corresponding to the region where the floating gate electrode 20 is provided (the region contacting the tunneling insulating film 12). In other words, the upper surface 11u1 is recessed from the upper surface 11u2.

The upper surface 11u1 of the semiconductor layer 11 is formed, for example, by the semiconductor layer 11 corresponding to the region between the floating gate electrodes 20 mutually adjacent along the X-axis direction being etched with the buried film 50f in the processing of step S160 of removing the portion (the unnecessary portion) of the buried film 50f.

There are no operational problems even in the case where the upper surface 11u1 of the semiconductor layer 11 corresponding to the region between the floating gate electrodes 20 is recessed from the upper surface 11u2 of the semiconductor layer 11 contacting the tunneling insulating film 12.

Thus, in the manufacturing method, for example, the second protruding portion side surface 20sf of the floating gate electrode 20 and the floating gate electrode upper conductive portion side surface 41sf of the floating gate electrode upper conductive portion 41 may be recessed from the inter-layer insulating film side surface 30sf of the inter-layer insulating film 30 as recited above by performing the processing of removing the portion (the unnecessary portion) of the buried film 50f formed to change the void 51 into the core conductive portion 50. Also, the upper surface 11u1 of the semiconductor layer corresponding to the region between the floating gate electrodes 20 may be recessed from the upper surface 11u2 of the semiconductor layer 11 contacting the tunneling insulating film 12. However, the embodiment is not limited thereto. The receding recited above may not occur depending on the combination of the materials used, the conditions of the implemented processing (the removal of the buried film 50f), etc.

### Second Embodiment

The overview of a semiconductor memory device manufactured using a manufacturing method according to a second embodiment is similar to the semiconductor memory device 110 described in regard to FIG. 2, FIG. 3A, and FIG. 3B; and a description is therefore omitted.

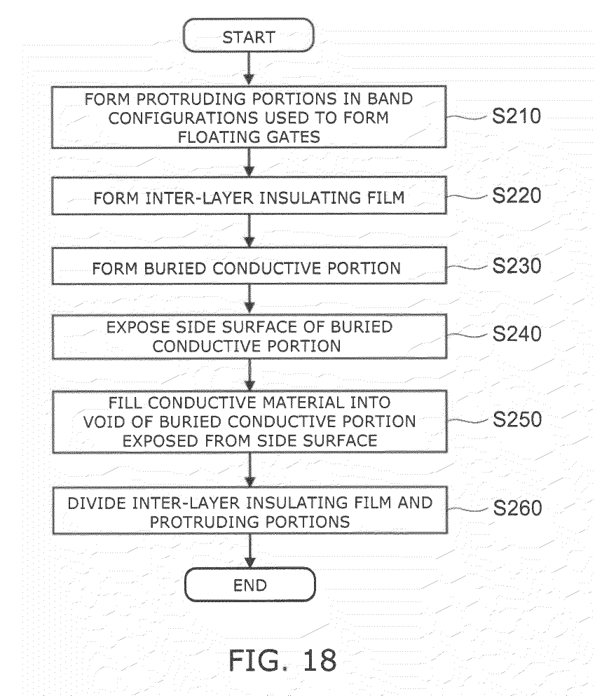

FIG. 18 is a flowchart illustrating the method for manufacturing the semiconductor memory device according to the second embodiment.

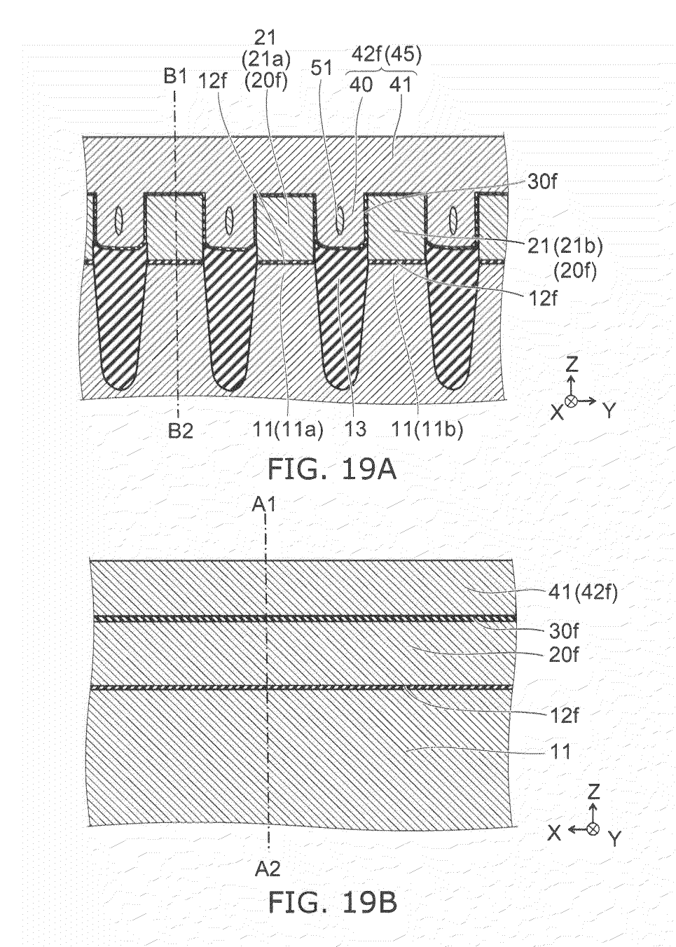

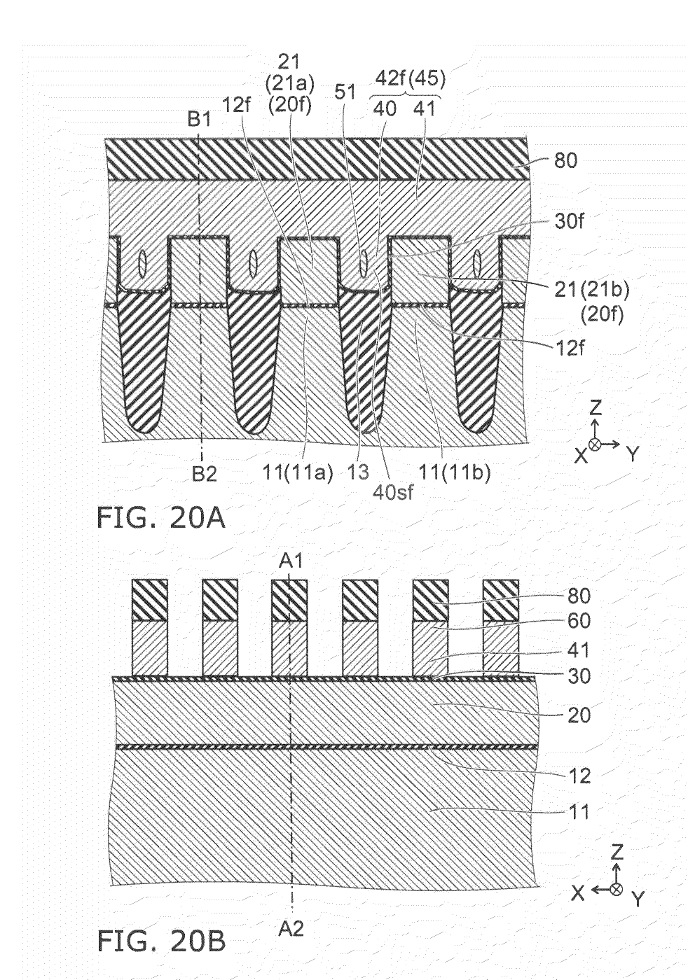

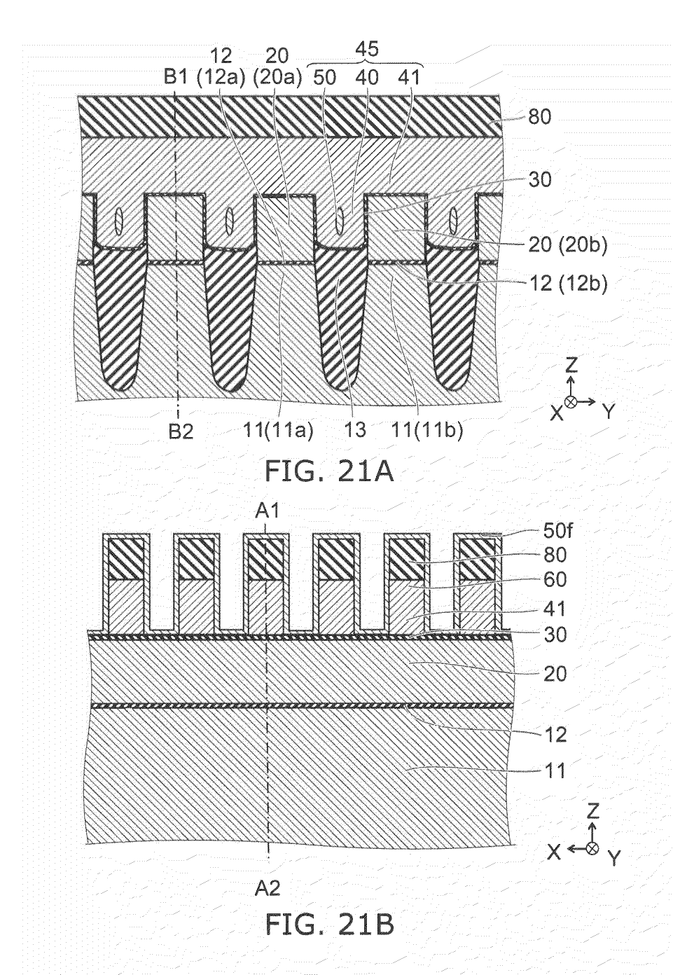

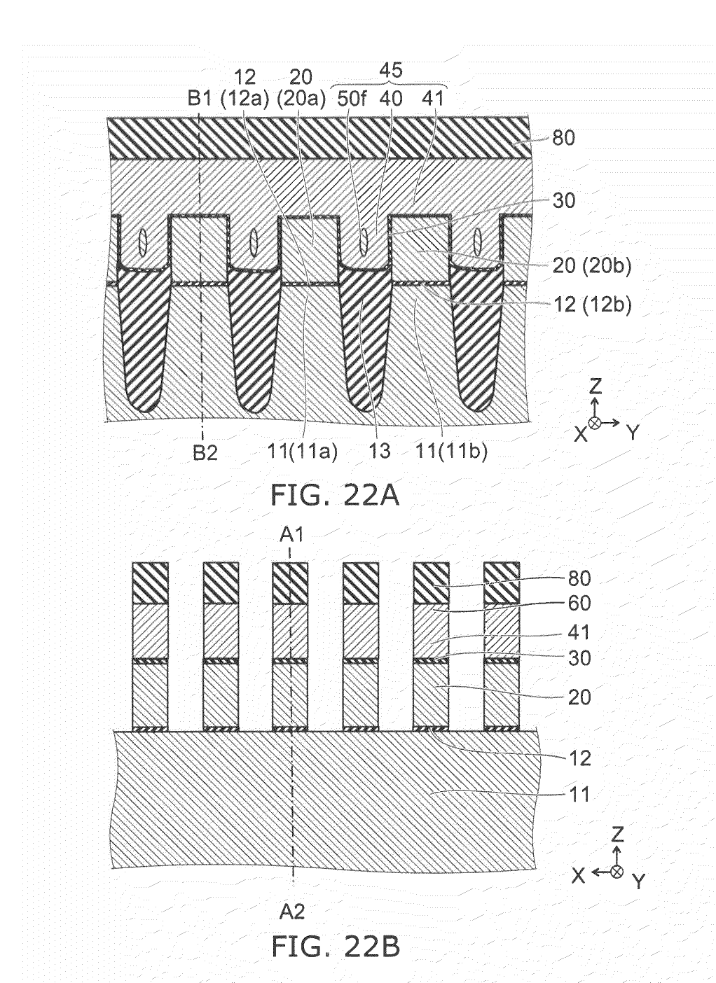

FIG. 19A, FIG. 19B, FIG. 20A, FIG. 20B, FIG. 21A, FIG. 21B, FIG. 22A, and FIG. 22B are schematic cross-sectional views in order of the processes, illustrating the method for manufacturing the semiconductor memory device according to the second embodiment.

FIG. 19A, FIG. 20A, FIG. 21A, and FIG. 22A are cross-sectional views corresponding to the cross section along line A1-A2 of FIG. 2; and FIG. 19B, FIG. 20B, FIG. 21B, and FIG. 22B are cross-sectional views corresponding to the cross section along line B1-B2 of FIG. 2.

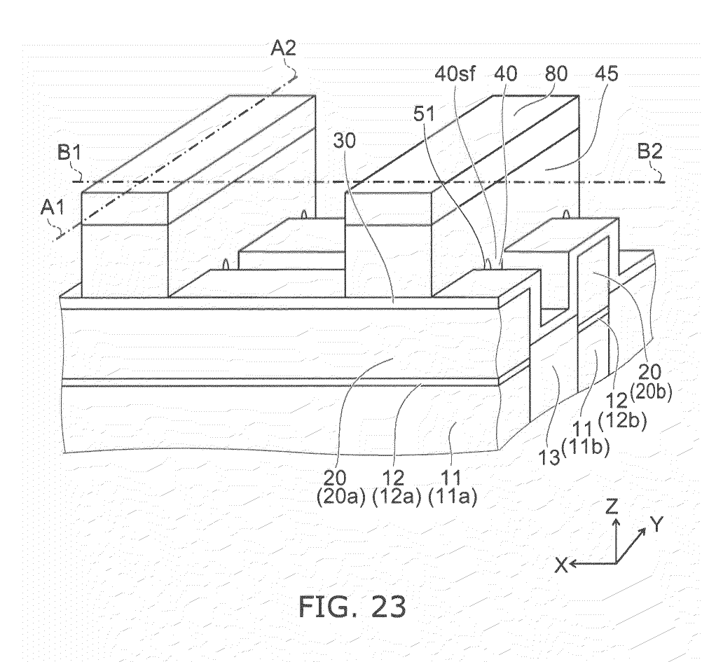

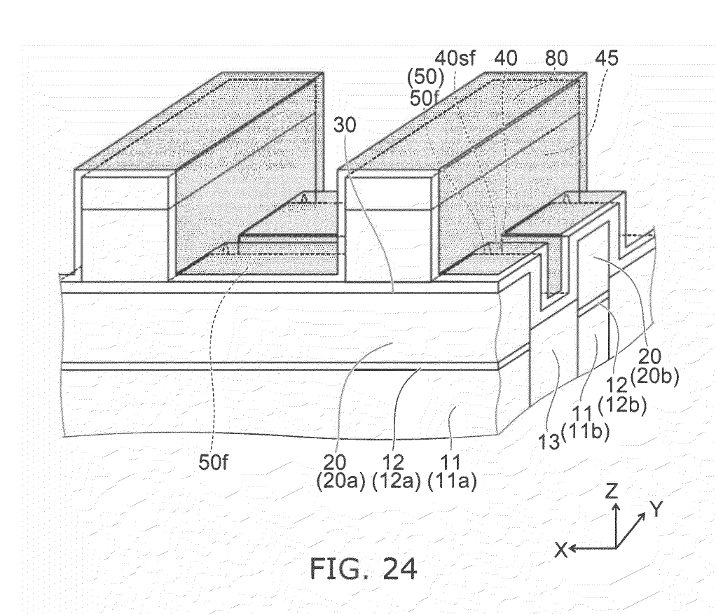

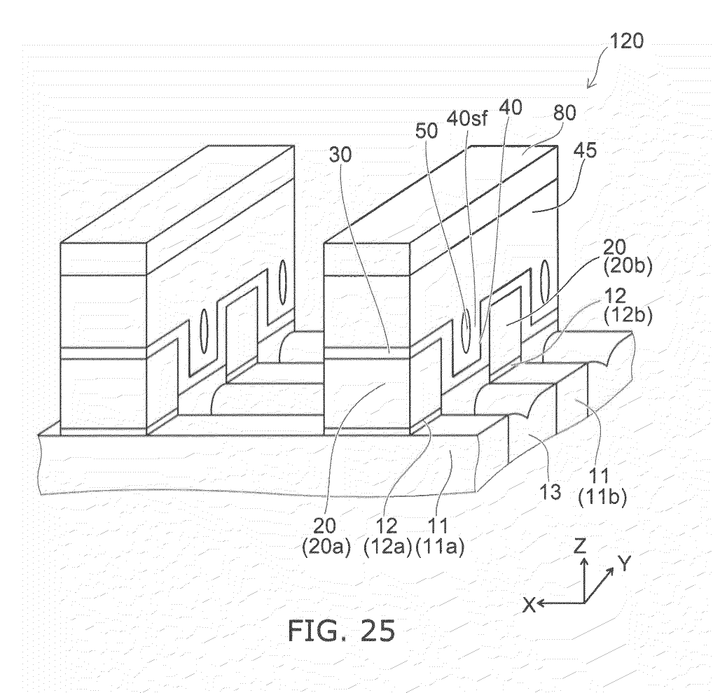

FIG. 23, FIG. 24, and FIG. 25 are schematic perspective views in order of the processes, illustrating the method for manufacturing the semiconductor memory device according to the second embodiment.

FIG. 23 corresponds to the process illustrated in FIG. 20A and FIG. 20B; FIG. 24 corresponds to the process illustrated in FIG. 21A and FIG. 21B; and FIG. 25 corresponds to the process illustrated in FIG. 22A and FIG. 22B.

In the manufacturing method according to the embodiment as illustrated in FIG. 18, the multiple protruding portions 21 are formed in band configurations used to form the floating gate electrode 20 on the major surface 11ms of the semiconductor layer 11 to extend along the first direction (the X-axis direction) parallel to the major surface 11ms (step S210). In this process, for example, the processing described in regard to FIG. 4A, FIG. 4B, FIG. 5A, and FIG. 5B is performed. Thereby, the trench 21t is made between the multiple protruding portions 21.

Then, the inter-layer insulating film 30 (the insulating film 30f) is formed to cover the multiple protruding portions 21 and the inner surface of the trench 21t between the multiple protruding portions 21 (step S220).

Continuing, the buried conductive portion 40 is formed by filling the first conductive material into the space inside the trench 21t with the inter-layer insulating film 30 (the insulating film 30f) provided around the space (step S230).

For example, as illustrated in FIGS. 19A and 19B, the insulating film 30f used to form the inter-layer insulating film 30 (e.g., a silicon oxide film) is formed; and the conductive film 42f used to form the control gate electrode 42 (e.g., a polysilicon film) is formed. Although the conductive film 60f used to form the upper layer control gate electrode 60 (e.g., a polysilicon film and/or a silicide film) may be formed thereon, a description of the upper layer control gate electrode 60 and the conductive film 60f is omitted to simplify the description. The portion of the conductive film 42f between the protruding portions 21 used to form the floating gate electrodes 20 (e.g., between the first protruding portion 21a and the second protruding portion 21b) becomes the buried conductive portion 40; and the portion of the conductive film 42f on the protruding portion 21 becomes the floating gate electrode upper conductive portion 41.

At this time, as illustrated in FIGS. 19A and 19B, the void 51 forms in the buried conductive portion 40.

Then, as illustrated in FIG. 18, the buried conductive portion side surface 40sf of the buried conductive portion 40 along the Y-axis direction (the second direction parallel to the major surface 11ms and non-parallel to the first direction) is exposed by dividing the buried conductive portion 40 along the first direction (the X-axis direction) (step S240).

For example, as illustrated in FIG. 20A, FIG. 20B, and FIG. 23, a mask 80 (e.g., a hard mask) is formed in a band configuration on the conductive film 42f used to form the control gate electrode 42 to extend along the Y-axis direction using lithography and etching; and the conductive film 42f is divided along the X-axis direction using the mask 80 as a mask. At this time, in the manufacturing method, the layers at the same level and lower than the insulating film 30f used to form the inter-layer insulating film 30 are not patterned. By this process, the control gate electrode 42 (the floating gate electrode upper conductive portion 41) is formed from the conductive film 42f extending in a band configuration in the Y-axis direction.

Then, the buried conductive portion side surface 40sf of the buried conductive portion 40 along the Y-axis direction is exposed by the buried conductive portion 40 being divided along the X-axis direction. The void 51 of the buried conductive portion 40 is exposed at the buried conductive portion side surface 40sf.

Subsequently, as illustrated in FIG. 18, the second conductive material is filled into the void 51 of the buried conductive portion 40 exposed at the buried conductive portion side surface 40sf (step S250).

For example, as illustrated in FIG. 21A, FIG. 21B, and FIG. 24, the buried film 50f of the second conductive material (e.g., a polysilicon film) is formed. In other words, the filling of the second conductive material may include a process of forming an amorphous silicon film. A process of polycrystalizing the amorphous silicon film also may be included.

Thereby, the core conductive portion 50 is formed in the void 51 by the buried film 50f being formed inside the void 51 of the buried conductive portion 40 exposed at the buried conductive portion side surface 40sf. In such a case as well, a film formation method having high fillability (CVD having a reaction-controlled film formation condition, film formation by ALD, etc.) is applied in the formation of the buried film 50f.

Subsequently, as illustrated in FIG. 18, the inter-layer insulating film 30 (the insulating film 30f) and the multiple protruding portions 21 are divided along the X-axis direction (step S260).

For example, as illustrated in FIG. 22A, FIG. 22B, and FIG. 25, the insulating film 30f and the multiple protruding portions 21 (the floating gate film 20f) are divided along the X-axis direction by performing patterning using the mask 80 as a mask.

In other words, the dividing of the inter-layer insulating film 30 (the insulating film 30f) and the multiple protruding portions 21 is a patterning using the mask 80 used in the dividing of the buried conductive portion 40 as a mask.

Thereby, the floating gate electrode 20 is formed from the floating gate film 20f in a columnar configuration. Then, the inter-layer insulating film 30 is formed to cover the upper surface of the floating gate electrode 20 and the side surface of the floating gate electrode 20 along the X-axis direction. The tunneling insulating film 12 is formed from the insulating film 12f.

In this patterning, the portion of the inter-layer insulating film 30 (the insulating film 30f) not covered with the buried conductive portion 40 and the portion of the multiple protruding portions 21 not covered with the buried conductive portion 40 are removed.

In this patterning, the buried film 50f formed on the entire front surface of the patterning body is removed simultaneously.

The buried film 50f formed on the buried conductive portion side surface 40sf and the buried film 50f formed on the inter-layer insulating film 30 (the insulating film 30f) when filling the second conductive material (the buried film 50f) into the void 51 are removed by the patterning of this dividing.

Although the buried film 50f positioned under the mask 80 may remain on the buried conductive portion side surface 40sf of the buried conductive portion 40 at this time, the remaining buried film 50f may be removed using wet etching, dry etching having high isotropy, etc. The buried film 50f on the buried conductive portion side surface 40sf may be removed by cleaning, etc., of a process implemented subsequently.

Then, the semiconductor memory device 120 (not illustrated) is manufactured by forming the impurity diffusion region 11d and the inter-layer insulating layer 70.

### Third Embodiment

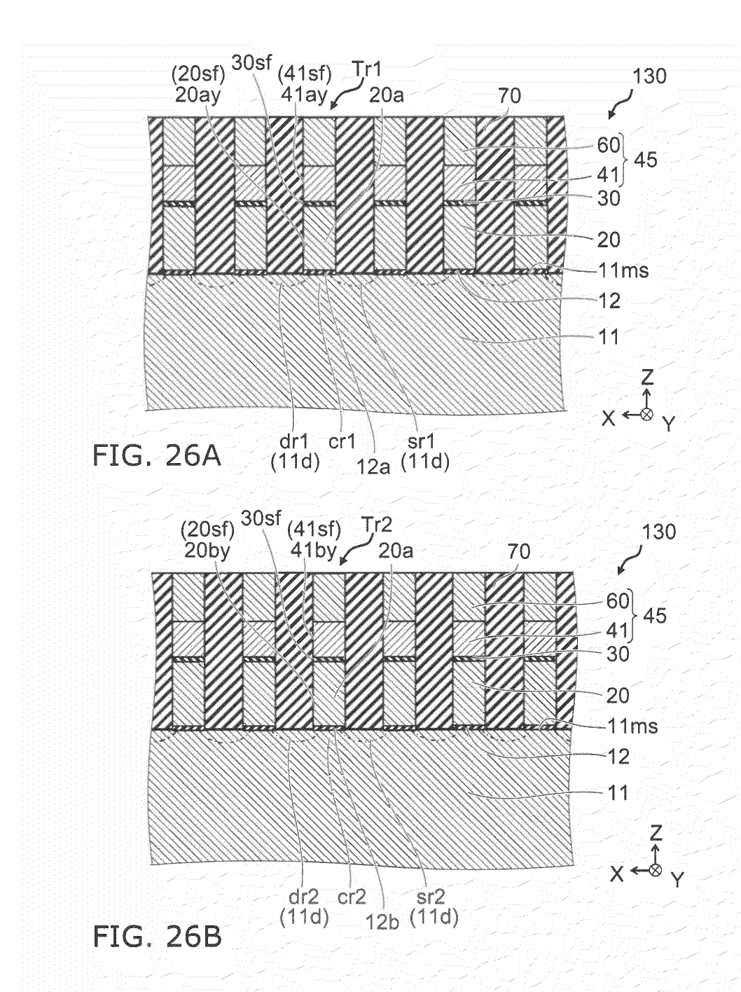

FIG. 26A and FIG. 26B are schematic cross-sectional views illustrating the configuration of a semiconductor memory device according to a third embodiment.

The overview of the configuration of the semiconductor memory device 130 according to the embodiment is similar to the overview of the configuration of the semiconductor memory device 110 described in regard to FIG. 2, FIG. 3A, and FIG. 3B.

FIG. 26A corresponds to the cross section along line B1-B2 of FIG. 2; and FIG. 26B corresponds to the cross section along line B3-B4 of FIG. 2.

The configuration of the cross section along line A1-A2 of the semiconductor memory device 130 is similar to that of FIG. 3A.

As illustrated in FIG. 2, FIG. 3A, FIG. 26A, and FIG. 26B, the semiconductor memory device 130 according to the embodiment includes a first transistor unit Tr1, a second transistor unit Tr2, the inter-layer insulating film 30, and the control gate electrode 42.

As illustrated in FIG. 26A, the first transistor unit Tr1 includes a first source region sr1, a first drain region dr1, a first channel region cr1, a first tunneling insulating film 12a, and the first floating gate electrode 20a.

The first source region sr1 is provided in the major surface 11ms of the semiconductor layer 11. The first drain region dr1 is provided in the major surface 11ms of the semiconductor layer 11 to face the first source region sr1 in the X-axis direction (the first direction). The first channel region cr1 is provided in the major surface 11ms of the semiconductor layer 11 between the first source region sr1 and the first drain region dr1. The first tunneling insulating film 12a is provided on the first channel region cr1. The first floating gate electrode 20a is provided on the first tunneling insulating film 12a.

As illustrated in FIG. 2 and FIG. 3A, the second transistor unit Tr2 is arranged with the first transistor unit Tr1 in the Y-axis direction (the second direction) non-parallel to the X-axis direction.

As illustrated in FIG. 26A, the second transistor unit Tr2 includes a second source region sr2, a second drain region dr2, a second channel region cr2, a second tunneling insulating film 12b, and the second floating gate electrode 20b.

The second source region sr2 is provided in the major surface 11ms of the semiconductor layer 11. The second drain region dr2 is provided in the major surface 11ms of the semiconductor layer 11 to face the second source region sr2 in the X-axis direction. The second channel region cr2 is provided in the major surface 11ms of the semiconductor layer 11 between the second source region sr2 and the second drain region dr2. The second tunneling insulating film 12b is provided on the second channel region cr2. The second floating gate electrode 20b is provided on the second tunneling insulating film 12b.

As illustrated in FIG. 3A, the inter-layer insulating film 30 includes the first side wall portion 30as contacting the side wall of the first floating gate electrode 20a on the second floating gate electrode 20b side, the first apical portion 30at contacting the upper surface of the first floating gate electrode 20a, the second side wall portion 30bs contacting the side wall of the second floating gate electrode 20b on the first floating gate electrode 20a side, and the second apical portion 30bt contacting the upper surface of the second floating gate electrode 20b.

The control gate electrode 42 includes the buried conductive portion 40 buried between the first side wall portion 30as and the second side wall portion 30bs.

The buried conductive portion 40 includes the core conductive portion 50 in which the conductive material is filled into the void 51.

As illustrated in FIG. 26A and FIG. 26B, a side surface 20ay of the first floating gate electrode 20a along the Y-axis direction is recessed from the inter-layer insulating film side surface 30sf of the inter-layer insulating film 30 along the Y-axis direction. A side surface 20by of the second floating gate electrode 20b along the Y-axis direction is recessed from the inter-layer insulating film side surface 30sf of the inter-layer insulating film 30 along the Y-axis direction.

As illustrated in FIG. 3A, the control gate electrode 42 further includes the first floating gate electrode upper conductive portion 41a provided on the first apical portion 30at and the second floating gate electrode upper conductive portion 41b provided on the second apical portion 30bt.

A side surface 41ay (one of the floating gate electrode upper conductive portion side surface 41sf) of the first floating gate electrode upper conductive portion 41a along the Y-axis direction and a side surface 41by (one other floating gate electrode upper conductive portion side surface 41sf) of the second floating gate electrode upper conductive portion 41b along the Y-axis direction are recessed from the inter-layer insulating film side surface 30sf of the inter-layer insulating film 30 along the Y-axis direction.

In other words, the semiconductor memory device 130 has a configuration similar to that of the semiconductor memory device 111 described in regard to FIG. 16A and FIG. 16B.

Thereby, as described above, the leak current LC due to the electric field between the floating gate electrode 20 and the control gate electrode 42 can be suppressed. Thereby, the programming characteristics can be improved.

The semiconductor memory device 130 may have a configuration similar to that of the semiconductor memory device 112 described in regard to FIG. 17. In other words, the upper surface 11u1 of the semiconductor layer 11 corresponding to the region between the first floating gate electrode 20a and the second floating gate electrode 20b is positioned lower than the boundary (e.g., the upper surface 11u2 of the semiconductor layer 11) between the first tunneling insulating film 12a and the semiconductor layer 11. The upper surface 11u1 is positioned lower than the boundary between the second tunneling insulating film 12b and the semiconductor layer 11.

Although the case is described in the description recited above where the embodiments are applied to a floating gate semiconductor memory device, the embodiments are not limited thereto. The semiconductor device to which the embodiments are applied is arbitrary. In the methods for manufacturing the semiconductor device according to the embodiments, the multiple protruding portions 21 are formed in band configurations on the element formation region of the semiconductor layer 11 to extend in the X-axis direction (the first direction) parallel to the major surface 11ms of the semiconductor layer 11 (e.g., step S110 or step S210); the first protruding portion side surfaces of the multiple protruding portions 21 along the X-axis direction are formed and the buried portion (e.g., the buried conductive portion 40) is formed by forming the first film into the space between the multiple protruding portions 21 with the bottom face of the trench provided around the space (e.g., step S130 or step S230); the buried portion side surface (e.g., the buried conductive portion side surface 40sf) of the buried portion (the buried conductive portion 40) along the X-axis direction is exposed by dividing the buried portion along the X-axis direction (e.g., step S140 or step S240); and the second film is filled into the void exposed at the buried portion side surface (e.g., step S150 or step S250).

Then, a portion (an unnecessary portion) of the second film is removed if necessary (step S160).

The second protruding portion side surface 20sf of the first film along the Y-axis direction can be exposed together when exposing the buried portion side surface (e.g., the buried conductive portion side surface 40sf) of the buried portion recited above (the buried conductive portion 40) along the Y-axis direction (e.g., step S140).

After the second film is filled into the void 51 exposed at the buried conductive portion side surface 40sf, the processing of dividing the multiple protruding portions 21 along the X-axis direction (e.g., step S260) also may be implemented. In such a case, a portion (an unnecessary portion) of the second film also may be removed in the processing of dividing the multiple protruding portions 21 along the X-axis direction. In such a case as well, a processing of removing the portion (the unnecessary portion) of the second film also may be performed.

As described above, according to the embodiments, a semiconductor memory device in which the occurrence of operation errors can be suppressed and a method for manufacturing the same can be provided.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components such as semiconductor layers, semiconductor substrates, tunneling insulating films, floating gate electrodes, inter-layer insulating films, inter-layer insulating layers, control gate electrodes, etc., included in semiconductor memory devices from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all methods for manufacturing semiconductor memory devices and semiconductor memory devices practicable by an appropriate design modification by one skilled in the art based on the methods for manufacturing the semiconductor memory devices and the semiconductor memory devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for manufacturing a semiconductor memory device, comprising:
forming a plurality of protruding portions in band configurations on a major surface of a semiconductor layer to extend along a first direction parallel to the major surface, the plurality of protruding portions being used to form electrodes;
forming an inter-layer insulating film to cover the plurality of protruding portions and an inner surface of a trench between the plurality of protruding portions;
forming a buried conductive portion by filling a first conductive material into a space inside the trench with the inter-layer insulating film provided around the space;
exposing a buried conductive portion side surface of the buried conductive portion along a second direction parallel to the major surface and non-parallel to the first direction by dividing the buried conductive portion along the first direction;
filling a second conductive material into a void of the buried conductive portion exposed at the buried conductive portion side surface; and
removing one portion of the second conductive material.

2. The method according to claim 1, wherein a length of the protruding portion along a third direction perpendicular to the major surface is longer than a length of the protruding portion along the second direction.

3. The method according to claim 1, wherein the removing of the one portion of the second conductive material includes removing the second conductive material provided on at least one selected from an upper surface of the plurality of protruding portions, a side surface of the inter-layer insulating film, the buried conductive portion side surface, an upper surface of the inter-layer insulating film, and an upper surface of the buried conductive portion.

4. The method according to claim 3, wherein the second conductive material provided on the at least one is provided on the at least one when filling the second conductive material into the void.

5. The method according to claim 1, wherein the removing of the one portion of the second conductive material includes removing the second conductive material provided on a side surface of at least one of the plurality of protruding portions along the second direction.

6. The method according to claim 1, wherein at least a portion of a side wall of each of the plurality of protruding portions is at least one selected from perpendicular to the major surface and reverse-tapered with respect to the major surface.

7. The method according to claim 1, wherein the filling of the second conductive material includes implementing at least one selected from film formation by CVD having a reaction-controlled film formation condition and film formation by atomic layer deposition.

8. The method according to claim 1, wherein the removing of the one portion of the second conductive material includes wet etching.

9. The method according to claim 1, wherein the filling of the first conductive material includes forming an amorphous silicon film.

10. The method according to claim 1, wherein the filling of the second conductive material includes forming an amorphous silicon film.

11. The method according to claim 1, wherein the second conductive material includes at least one selected from a silicide, a metal nitride, and a metal.

12. The method according to claim 1, wherein the electrode is a floating gate of the semiconductor memory device.

13. A method for manufacturing a semiconductor memory device, comprising:
forming a plurality of protruding portions in band configurations on a major surface of a semiconductor layer to extend along a first direction parallel to the major surface, the plurality of protruding portions being used to form electrodes;
forming an inter-layer insulating film to cover the plurality of protruding portions and an inner surface of a trench between the plurality of protruding portions;
forming a buried conductive portion by filling a first conductive material into a space inside the trench with the inter-layer insulating film provided around the space;
exposing a buried conductive portion side surface of the buried conductive portion along a second direction parallel to the major surface and non-parallel to the first direction by dividing the buried conductive portion along the first direction;
filling a second conductive material into a void of the buried conductive portion exposed at the buried conductive portion side surface; and
dividing the inter-layer insulating film and the plurality of protruding portions along the first direction.

14. The method according to claim 13, wherein the dividing of the inter-layer insulating film and the plurality of protruding portions includes dividing using a mask used in the dividing of the buried conductive portion.

15. The method according to claim 13, wherein a length of the protruding portion along a third direction perpendicular to the major surface is longer than a length of the protruding portion along the second direction.

16. The method according to claim 13, wherein the filling of the second conductive material includes implementing at least one selected from CVD having a reaction-controlled film formation condition and atomic layer deposition.

17. The method according to claim 13, wherein the filling of the second conductive material includes forming an amorphous silicon film.

18. The method according to claim 13, wherein the dividing includes removing at least a portion of at least one selected from a film of the second conductive material formed on the buried conductive portion side surface and a film of the second conductive material formed on the inter-layer insulating film.

19. The method according to claim 13, wherein the electrode is a floating gate of the semiconductor memory device.

20. A semiconductor memory device, comprising:
a first transistor unit including
a first source region provided in a major surface of a semiconductor layer,
a first drain region provided in the major surface to face the first source region in a first direction,
a first channel region provided in the major surface between the first source region and the first drain region,
a first tunneling insulating film provided on the first channel region, and
a first electrode provided on the first tunneling insulating film;
a second transistor unit arranged with the first transistor unit in a second direction non-parallel to the first direction, the second transistor unit including
a second source region provided in the major surface,
a second drain region provided in the major surface to face the second source region in the first direction,
a second channel region provided in the major surface between the second source region and the second drain region,
a second tunneling insulating film provided on the second channel region, and
a second electrode provided on the second tunneling insulating film;
an inter-layer insulating layer including a first side wall portion contacting a side wall of the first electrode on a side of the second electrode, a first apical portion contacting an upper surface of the first electrode, a second side wall portion contacting a side wall of the second electrode on a side of the first electrode, and a second apical portion contacting an upper surface of the second electrode; and
a control gate electrode including a buried conductive portion buried between the first side wall portion and the second side wall portion,
the buried conductive portion including a core conductive portion having a conductive material filled into a void,
a side surface of the first electrode along the second direction being recessed from a side surface of the inter-layer insulating film along the second direction.
